(19) United States
(12) Patent Application Publication
(10) Pub. No.: US 2025/0391477 A1
(43) Pub. Date: Dec. 25, 2025

(54) MEMORY CONFIGURED TO PROGRAM MEMORY CELLS HAVING MULTIPLE DIFFERENT CHANNEL VOLTAGE LEVELS AND METHODS OF THEIR OPERATION

(71) Applicant: MICRON TECHNOLOGY, INC., Boise, ID (US)

(72) Inventors: Jeffrey S. McNeil, Nampa, ID (US); Tomoko Ogura Iwasaki, San Jose, CA (US); Sheyang Ning, San Jose, CA (US); Lawrence Celso Miranda, San Jose, CA (US)

(73) Assignee: MICRON TECHNOLOGY, INC., Boise, ID (US)

(21) Appl. No.: 19/240,644

(22) Filed: Jun. 17, 2025

Related U.S. Application Data
(60) Provisional application No. 63/661,658, filed on Jun. 19, 2024.

(51) Int. Cl. G11C 16/10; G11C 16/04; G11C 16/34

(52) U.S. Cl. CPC G11C 16/102; G11C 16/0483; G11C 16/3404

(57) ABSTRACT

Memories might include a controller configured to cause the memory to develop a respective voltage level in a channel of each memory cell of a plurality of subsets of memory cells selected for a programming operation, wherein each of the memory cells is connected to a selected access line of the programming operation, and wherein each of the subsets of memory cells corresponds to a respective voltage level of the plurality of voltage levels in a one-to-one relationship; and to apply a programming voltage level of the programming operation to the selected access line. Each of the memory cells has a respective desired data state of a plurality of possible data states of the programming operation, and the respective desired data states of the memory cells of at least one of the subsets of memory cells includes two or more data states of the plurality of possible data states.

### RELATED APPLICATION

This application claims the benefit of U.S. Provisional Application No. 63/661,658, filed on Jun. 19, 2024, hereby incorporated herein in its entirety by reference.

### TECHNICAL FIELD

The present disclosure relates generally to integrated circuits, and, in particular, in one or more embodiments, the present disclosure relates to memories configured to program memory cells having multiple different channel voltage levels and methods of their operation.

### BACKGROUND

Memories (e.g., memory devices) are typically provided as internal, semiconductor, integrated circuit devices in computers or other electronic devices. There are many different types of memory including random-access memory (RAM), read only memory (ROM), dynamic random access memory (DRAM), synchronous dynamic random access memory (SDRAM), and flash memory.

Flash memory has developed into a popular source of non-volatile memory for a wide range of electronic applications. Flash memory typically uses a one-transistor memory cell that allows for high memory densities, high reliability, and low power consumption. Changes in threshold voltage (Vt) of the memory cells, through programming (which is often referred to as writing) of charge storage structures (e.g., floating gates or charge traps) or other physical phenomena (e.g., phase change or polarization), determine the data state (e.g., data value) of each memory cell. Common uses for flash memory and other non-volatile memory include personal computers, personal digital assistants (PDAs), digital cameras, digital media players, digital recorders, games, appliances, vehicles, wireless devices, mobile telephones, and removable memory modules, and the uses for non-volatile memory continue to expand.

A NAND flash memory is a common type of flash memory device, so called for the logical form in which the basic memory cell configuration is arranged. Typically, the array of memory cells for NAND flash memory is arranged such that the control gate of each memory cell of a row of the array is connected together to form an access line, such as a word line. Columns of the array include strings (often termed NAND strings) of memory cells connected together in series between a pair of select gates, e.g., a source select transistor and a drain select transistor. A source select transistor might be connected to a source, while a drain select transistor might be connected to a data line, such as column bit line. Variations using more than one select gate between a string of memory cells and the source, and/or between the string of memory cells and the data line, are known.

In programming memory, memory cells might be programmed as what are often termed single-level cells (SLC). SLC might use a single memory cell to represent one digit (e.g., one bit) of data. For example, in SLC, a Vt of 2.5V or higher might indicate a programmed memory cell (e.g., representing a logical 0) while a Vt of −0.5V or lower might indicate an erased memory cell (e.g., representing a logical 1). Such memory might achieve higher levels of storage capacity by including multi-level cells (MLC), triple-level cells (TLC), quad-level cells (QLC), etc., or combinations thereof in which the memory cell has multiple levels that enable more digits of data to be stored in each memory cell. For example, MLC might be configured to store two digits of data per memory cell represented by four Vt ranges, TLC might be configured to store three digits of data per memory cell represented by eight Vt ranges, QLC might be configured to store four digits of data per memory cell represented by sixteen Vt ranges, and so on.

### BRIEF DESCRIPTION OF THE DRAWINGS

FIG. 1 is a simplified block diagram of a memory in communication with a processor as part of an electronic system, according to an embodiment.

FIGS. 2A-2B are schematics of portions of an array of memory cells as could be used in a memory of the type described with reference to FIG. 1.

FIG. 3 is a conceptual depiction of threshold voltage distributions of a plurality of memory cells as could be used with embodiments.

FIG. 4 is a timing diagram depicting voltage levels of a selected access line for a programming operation as could be used with embodiments.

FIG. 5 is a timing diagram depicting voltage levels of a selected access line for a programming operation as could be used with embodiments.

FIG. 6 depicts a modified schematic of a portion of an array of memory cells as could be used in a memory of the type described with reference to FIG. 1.

FIG. 7 illustrates a timing diagram for an equilibrium pulse of a programming operation in accordance with an embodiment.

FIG. 8 is a timing diagram depicting channel voltage levels that might result from the application of the equilibrium pulse of FIG. 7.

FIG. 9 is a conceptual depiction of threshold voltage distributions of a plurality of memory cells that might result from the application of an equilibrium pulse in accordance with an embodiment.

FIG. 10 is a flowchart of a method of operating a memory in accordance with an embodiment.

FIG. 11 is a flowchart of a method of operating a memory in accordance with another embodiment.

FIG. 12 is a flowchart of a method of operating a memory in accordance with a further embodiment.

FIGS. 13A-13B are a flowchart of a method of operating a memory in accordance with a still further embodiment.

FIG. 14 is a flowchart of a method of operating a memory in accordance with a still further embodiment.

FIG. 15 is a flowchart of a method of operating a memory in accordance with a still further embodiment.

### DETAILED DESCRIPTION

In the following detailed description, reference is made to the accompanying drawings that form a part hereof, and in which is shown, by way of illustration, specific embodiments. In the drawings, like reference numerals describe substantially similar components throughout the several views. Other embodiments might be utilized and structural, logical and electrical changes might be made without departing from the scope of the present disclosure. The following detailed description is, therefore, not to be taken in a limiting sense.

The term “semiconductor” used herein can refer to, for example, a layer of material, a wafer, or a substrate, and includes any base semiconductor structure. “Semiconductor” is to be understood as including silicon-on-sapphire (SOS) technology, silicon-on-insulator (SOI) technology, thin film transistor (TFT) technology, doped and undoped semiconductors, epitaxial layers of a silicon supported by a base semiconductor structure, as well as other semiconductor structures well known to one skilled in the art. Furthermore, when reference is made to a semiconductor in the following description, previous process steps might have been utilized to form regions/junctions in the base semiconductor structure, and the term semiconductor can include the underlying layers containing such regions/junctions.

The term “conductive” as used herein, as well as its various related forms, e.g., conduct, conductively, conducting, conduction, conductivity, etc., refers to electrically conductive unless otherwise apparent from the context. Similarly, the term “connecting” as used herein, as well as its various related forms, e.g., connect, connected, connection, etc., refers to electrically connecting by an electrically conductive path unless otherwise apparent from the context.

As used herein, multiple acts being performed concurrently will mean that each of these acts is performed for a respective time period, and each of these respective time periods overlaps, in part or in whole, with each of the remaining respective time periods. In other words, portions of each of those acts are simultaneously performed for at least some period of time.

It is recognized herein that even where values might be intended to be equal, variabilities and accuracies of industrial processing and operation might lead to differences from their intended values. These variabilities and accuracies will generally be dependent upon the technology utilized in fabrication and operation of the integrated circuit device. As such, if values are intended to be equal, those values are deemed to be equal regardless of their resulting values.

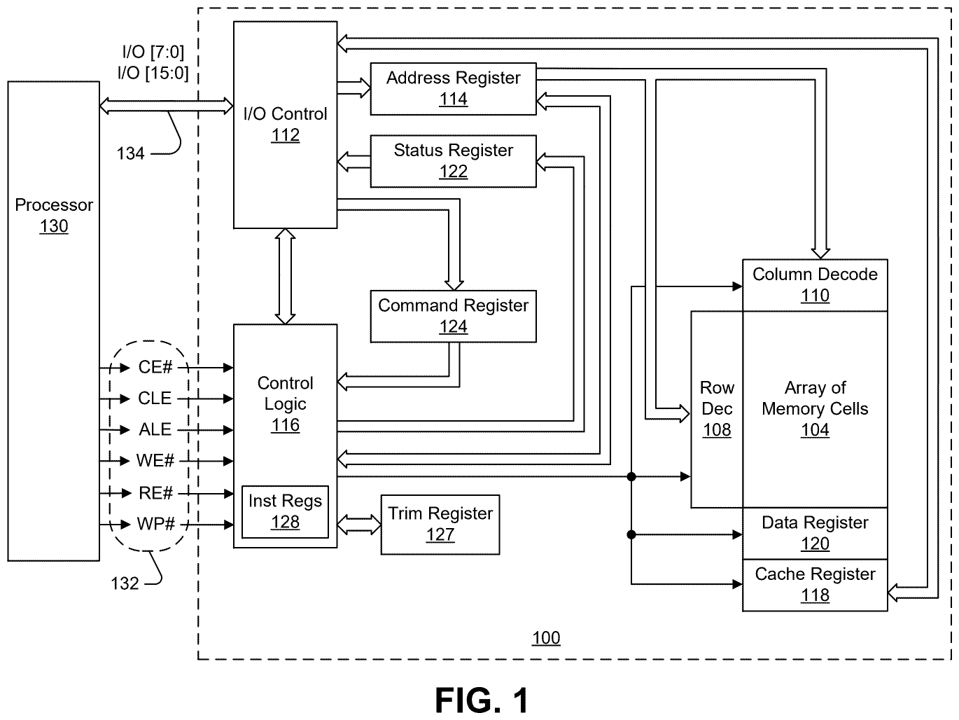

FIG. 1 is a simplified block diagram of a first apparatus, in the form of a memory (e.g., memory device) 100, in communication with a second apparatus, in the form of a processor 130, as part of a third apparatus, in the form of an electronic system, according to an embodiment. Some examples of electronic systems include personal computers, personal digital assistants (PDAs), digital cameras, digital media players, digital recorders, games, appliances, vehicles, wireless devices, mobile telephones and the like. The processor 130, e.g., a controller external to the memory device 100, might be a memory controller or other external host device.

Memory device 100 includes an array of memory cells 104 that might be logically arranged in rows and columns. Memory cells of a logical row are typically connected to the same access line (commonly referred to as a word line) while memory cells of a logical column are typically selectively connected to the same data line (commonly referred to as a bit line). A single access line might be associated with more than one logical row of memory cells and a single data line might be associated with more than one logical column. Memory cells (not shown in FIG. 1) of at least a portion of array of memory cells 104 are capable of being programmed to one of at least two different data states.

A row decode circuitry 108 and a column decode circuitry 110 are provided to decode address signals. Address signals are received and decoded to access the array of memory cells 104. Memory device 100 also includes input/output (I/O) control circuitry 112 to manage input of commands, addresses and data to the memory device 100 as well as output of data and status information from the memory device 100. An address register 114 is in communication with I/O control circuitry 112 and row decode circuitry 108 and column decode circuitry 110 to latch the address signals prior to decoding. A command register 124 is in communication with I/O control circuitry 112 and control logic 116 to latch incoming commands.

A controller (e.g., the control logic 116 internal to the memory device 100) controls access to the array of memory cells 104 in response to the commands and might generate status information for the external processor 130, i.e., control logic 116 is configured to perform array operations (e.g., sensing operations [which might include read operations and verify operations], programming operations and/or erase operations) on the array of memory cells 104 in accordance with embodiments. The control logic 116 is in communication with row decode circuitry 108 and column decode circuitry 110 to control the row decode circuitry 108 and column decode circuitry 110 in response to the addresses. The control logic 116 might include instruction registers 128 which might represent computer-usable memory for storing computer-readable instructions. For some embodiments, the instruction registers 128 might represent firmware. Alternatively, the instruction registers 128 might represent a grouping of memory cells, e.g., reserved block(s) of memory cells, of the array of memory cells 104.

Control logic 116 might also be in communication with a cache register 118. Cache register 118 latches data, either incoming or outgoing, as directed by control logic 116 to temporarily store data while the array of memory cells 104 is busy writing or reading, respectively, other data. During a programming operation (e.g., write operation), data might be passed from the cache register 118 to the data register 120 for transfer to the array of memory cells 104, then new data might be latched in the cache register 118 from the I/O control circuitry 112. During a read operation, data might be passed from the cache register 118 to the I/O control circuitry 112 for output to the external processor 130, then new data might be passed from the data register 120 to the cache register 118. The cache register 118 and/or the data register 120 might form (e.g., might form a portion of) a page buffer of the memory device 100. A data register 120 might further include sense circuits (not shown in FIG. 1) to sense a data state of a memory cell of the array of memory cells 104, e.g., by sensing a state of a data line connected to that memory cell. A status register 122 might be in communication with I/O control circuitry 112 and control logic 116 to latch the status information for output to the processor 130.

A trim register 127 might be in communication with the control logic 116. The trim register 127 might represent a volatile memory, latches, or other storage location, e.g., volatile or non-volatile. For some embodiments, the trim register 127 might represent a portion of the array of memory cells 104. Trims might be used by the memory to set values used by an array operation, e.g., voltage levels, timing characteristics, etc., or might be used to selectively activate or deactivate features of the memory. For various embodiments, the trim register 127 might store definitions of subsets of memory cells for programming operations, e.g., defining ranges of data states to be included in each subset of memory cells of a plurality of subsets of memory cells selected for the programming operation, and corresponding voltage levels to be used during the programming operation.

Memory device 100 receives control signals at control logic 116 from processor 130 over a control link 132. The control signals might include a chip enable CE #, a command latch enable CLE, an address latch enable ALE, a write enable WE #, a read enable RE #, and a write protect WP #. Additional or alternative control signals (not shown) might be further received over control link 132 depending upon the nature of the memory device 100. Memory device 100 receives command signals (which represent commands), address signals (which represent addresses), and data signals (which represent data) from processor 130 over a multiplexed input/output (I/O) bus 134 and outputs data to processor 130 over I/O bus 134.

For example, the commands might be received over input/output (I/O) pins [7:0] of I/O bus 134 at I/O control circuitry 112 and might then be written into command register 124. The addresses might be received over input/output (I/O) pins [7:0] of I/O bus 134 at I/O control circuitry 112 and might then be written into address register 114. The data might be received over input/output (I/O) pins [7:0] for an 8-bit device or input/output (I/O) pins [15:0] for a 16-bit device at I/O control circuitry 112 and then might be written into cache register 118. The data might be subsequently written into data register 120 for programming the array of memory cells 104. For another embodiment, cache register 118 might be omitted, and the data might be written directly into data register 120. Data might also be output over input/output (I/O) pins [7:0] for an 8-bit device or input/output (I/O) pins [15:0] for a 16-bit device. Although reference might be made to I/O pins, they might include any conductive nodes providing for electrical connection to the memory device 100 by an external device (e.g., processor 130), such as conductive pads or conductive bumps as are commonly used.

It will be appreciated by those skilled in the art that additional or alternative circuitry and signals can be provided, and that the memory device 100 of FIG. 1 has been simplified. It should be recognized that the functionality of the various block components described with reference to FIG. 1 might not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1.

Additionally, while specific I/O pins are described in accordance with popular conventions for receipt and output of the various signals, it is noted that other combinations or numbers of I/O pins (or other I/O node structures) might be used in the various embodiments.

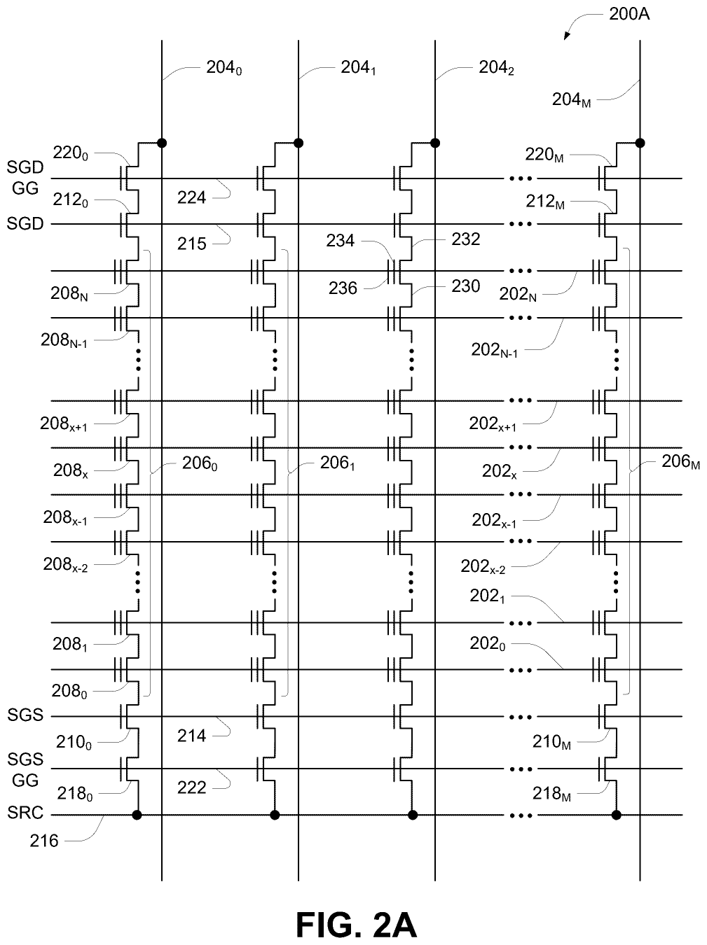

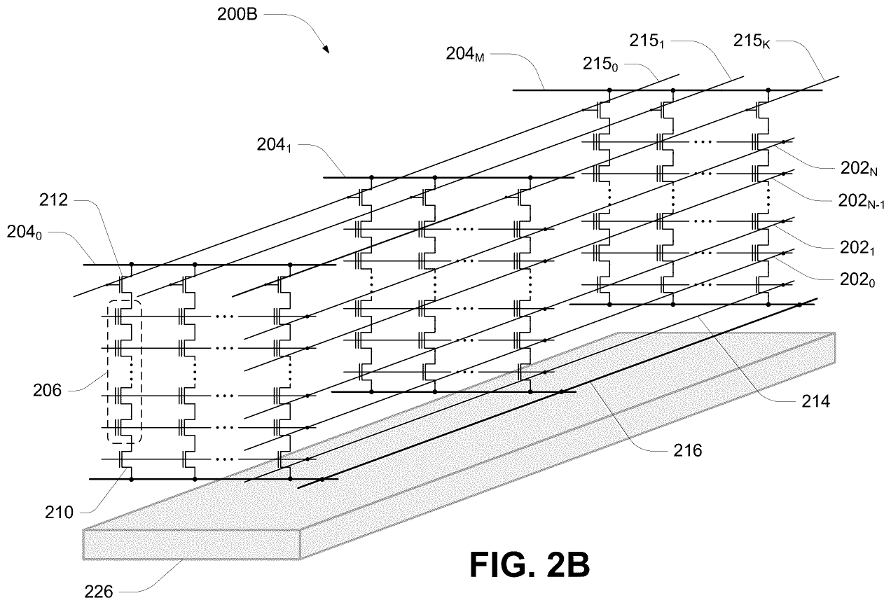

FIG. 2A is a schematic of a portion of an array of memory cells 200A, such as a NAND memory array, as could be used in a memory of the type described with reference to FIG. 1, e.g., as a portion of array of memory cells 104. Memory array 200A includes access lines, such as access lines (e.g., word lines) 202₀ to 202_{N}, and data lines, such as data lines (e.g., bit lines) 204₀ to 204_{M}. The access lines 202 might be connected to global access lines (e.g., global word lines), not shown in FIG. 2A, in a many-to-one relationship. For some embodiments, memory array 200A might be formed over a semiconductor that, for example, might be conductively doped to have a conductivity type, such as a p-type conductivity, e.g., to form a p-well, or an n-type conductivity, e.g., to form an n-well.

Memory array 200A might be arranged in rows (each corresponding to an access line 202) and columns (each corresponding to a data line 204). Each column might include a string of series-connected memory cells (e.g., non-volatile memory cells), such as one of NAND strings 206₀ to 206_{M}. Each NAND string 206 might be connected (e.g., selectively connected) to a common source (SRC) 216 and might include memory cells 208₀ to 208_{N}. The memory cells 208 might represent non-volatile memory cells for storage of data. Some of the memory cells 208 might represent dummy memory cells, e.g., memory cells not intended to store user data. Dummy memory cells are typically not accessible to a user of the memory, and are typically incorporated into the NAND string 206 for operational advantages, as are well understood.

The memory cells 208 of each NAND string 206 might be connected in series between a select gate 210 (e.g., a field-effect transistor), such as one of the select gates 210₀ to 210_{M} (e.g., that might be source select transistors, commonly referred to as select gate source), and a select gate 212 (e.g., a field-effect transistor), such as one of the select gates 212₀ to 212_{M} (e.g., that might be drain select transistors, commonly referred to as select gate drain). Select gates 210₀ to 210_{M} might be commonly connected to a select line 214, such as a source select line (SGS), and select gates 212₀ to 212_{M} might be commonly connected to a select line 215, such as a drain select line (SGD). Although depicted as traditional field-effect transistors, the select gates 210 and 212 might utilize a structure similar to (e.g., the same as) the memory cells 208. The select gates 210 and 212 might represent a plurality of select gates connected in series, with each select gate in series configured to receive a same or independent control signal. A control gate of each select gate 210 might be connected to select line 214. A control gate of each select gate 212 might be connected to select line 215.

The select gates 210 for each NAND string 206 might be connected in series between its memory cells 208 and a GIDL (gate-induced drain leakage) generator gate 218 (e.g., a field-effect transistor), such as one of the GIDL generator (GG) gates 218₀ to 218_{M}. The GG gates 218₀ to 218_{M} might be referred to as source GG gates. The source GG gates 218₀ to 218_{M} might each be connected (e.g., directly connected) to the source 216, and selectively connected to their respective NAND strings 206₀ to 206_{M}. Alternatively, a source select gate 210 and its GG gate 218 might represent a single gate, e.g., connected (e.g., directly connected) to the source 216, and connected (e.g., directly connected) to a respective NAND string 206.

The select gates 212 of each NAND string 206 might be connected in series between its memory cells 208 and a GG gate 220 (e.g., a field-effect transistor), such as one of the GG gates 220₀ to 220_{M}. The GG gates 220₀ to 220_{M} might be referred to as drain GG gates. The drain GG gates 220₀ to 220_{M} might be connected (e.g., directly connected) to their respective data lines 204₀ to 204_{M}, and selectively connected to their respective NAND strings 206₀ to 206_{M}. Alternatively, a drain select gate 212 and its GG gate 220 might represent a single gate, e.g., connected (e.g., directly connected) to a respective data line 204, and connected (e.g., directly connected) to a respective NAND string 206.

GG gates 218₀ to 218_{M} might be commonly connected to a control line 222, such as an SGS_GG control line, and GG gates 220₀ to 220_{M} might be commonly connected to a control line 224, such as an SGD_GG control line. Although depicted as traditional field-effect transistors, the GG gates 218 and 220 might utilize a structure similar to (e.g., the same as) the memory cells 208. The GG gates 218 and 220 might represent a plurality of GG gates connected in series, with each GG gate in series configured to receive a same or independent control signal. In general, the GG gates 218 and 220 might have threshold voltages different than (e.g., lower than) the threshold voltages of the select gates 210 and 212, respectively. Threshold voltages of the source GG gates 218 might be different than (e.g., higher than) threshold voltages of the drain GG gates 220. Threshold voltages of the GG gates 218 and 220 might be of an opposite polarity than, and/or might be lower than, threshold voltages of the select gates 210 and 212, respectively. For example, the select gates 210 and 212 might have positive threshold voltages (e.g., 2V to 4V), while the GG gates 218 and 220 might have negative threshold voltages (e.g., −1V to −4V). The GG gates 218 and 220 might be provided to assist in the generation of GIDL current into a channel of their corresponding NAND string 206 during an erase operation, for example.

A source of each GG gate 218 might be connected to common source 216. The drain of each GG gate 218 might be connected to a select gate 210 of the corresponding NAND string 206. For example, the drain of GG gate 218₀ might be connected to the source of select gate 210₀ of the corresponding NAND string 206₀. Therefore, in cooperation, each select gate 210 and GG gate 218 for a corresponding NAND string 206 might be configured to selectively connect that NAND string 206 to common source 216. A control gate of each GG gate 218 might be connected to control line 222.

The drain of each GG gate 220 might be connected to the data line 204 for the corresponding NAND string 206. For example, the drain of GG gate 220₀ might be connected to the data line 204₀ for the corresponding NAND string 206₀. The source of each GG gate 220 might be connected to a select gate 212 of the corresponding NAND string 206. For example, the source of GG gate 220₀ might be connected to select gate 212₀ of the corresponding NAND string 206₀. Therefore, in cooperation, each select gate 212 and GG gate 220 for a corresponding NAND string 206 might be configured to selectively connect that NAND string 206 to the corresponding data line 204. A control gate of each GG gate 220 might be connected to control line 224.

The memory array in FIG. 2A might be a quasi-two-dimensional memory array and might have a generally planar structure, e.g., where the common source 216, NAND strings 206 and data lines 204 extend in substantially parallel planes. Alternatively, the memory array in FIG. 2A might be a three-dimensional memory array, e.g., where NAND strings 206 might extend substantially perpendicular to a plane containing the common source 216 and to a plane containing the data lines 204 that might be substantially parallel to the plane containing the common source 216.

Typical construction of memory cells 208 includes a data-storage structure 234 (e.g., a floating gate, charge trap, or other structure configured to store charge) that can determine a data state of the memory cell (e.g., through changes in threshold voltage), and a control gate 236, as shown in FIG. 2A. The data-storage structure 234 might include both conductive and dielectric structures while the control gate 236 is generally formed of one or more conductive materials. In some cases, memory cells 208 might further have a defined source/drain (e.g., source) 230 and a defined source/drain (e.g., drain) 232. Memory cells 208 have their control gates 236 connected to (and in some cases form) an access line 202.

A column of the memory cells 208 might be a NAND string 206 or a plurality of NAND strings 206 selectively connected to a given data line 204. A row of the memory cells 208 might be memory cells 208 commonly connected to a given access line 202. A row of memory cells 208 can, but need not, include all memory cells 208 commonly connected to a given access line 202. Rows of memory cells 208 might often be divided into one or more groups of physical pages of memory cells 208, and physical pages of memory cells 208 often include every other memory cell 208 commonly connected to a given access line 202. For example, memory cells 208 commonly connected to access line 202_{N} and selectively connected to even data lines 204 (e.g., data lines 204₀, 204₂, 204₄, etc.) might be one physical page of memory cells 208 (e.g., even memory cells) while memory cells 208 commonly connected to access line 202_{N} and selectively connected to odd data lines 204 (e.g., data lines 204₁, 204₃, 204₅, etc.) might be another physical page of memory cells 208 (e.g., odd memory cells). Although data lines 204₃-204₅ are not explicitly depicted in FIG. 2A, it is apparent from the figure that the data lines 204 of the array of memory cells 200A might be numbered consecutively from data line 204₀ to data line 204_{M}. Other groupings of memory cells 208 commonly connected to a given access line 202 might also define a physical page of memory cells 208. For certain memory devices, all memory cells commonly connected to a given access line might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells might include those memory cells that are configured to be erased together, such as all memory cells connected to access lines 202₀-202_{N} (e.g., all NAND strings 206 sharing common access lines 202). Unless expressly distinguished, a reference to a page of memory cells herein refers to the memory cells of a logical page of memory cells.

FIG. 2B is another schematic of a portion of an array of memory cells 200B as could be used in a memory of the type described with reference to FIG. 1, e.g., as a portion of array of memory cells 104. Like numbered elements in FIG. 2B correspond to the description as provided with respect to FIG. 2A. FIG. 2B provides additional detail of one example of a three-dimensional NAND memory array structure. For clarity, the GG gates and their control lines are not depicted in FIG. 2B.

The three-dimensional NAND memory array 200B might incorporate vertical structures which might include conductively-doped semiconductor pillars, which might be solid or hollow, around which memory cells of NAND strings 206 might be formed. A portion of a pillar might act as a body or channel (e.g., channel region) of the memory cells of NAND strings 206, e.g., a region through which current might flow when a memory cell, e.g., a field-effect transistor, is activated. Each of the NAND strings 206 might be selectively connected to a data line 204₀-204_{M} by a select gate 212 and to a common source 216 by a select gate 210. Multiple NAND strings 206 might be selectively connected to the same data line 204. Subsets of NAND strings 206 can be connected to their respective data lines 204 by biasing the select lines 215₀-215_{K} to selectively activate particular select gates 212 each between a NAND string 206 and a data line 204. The select gates 210 can be activated by biasing the select line 214. Each access line 202 might be connected to multiple rows of memory cells of the memory array 200B. Rows of memory cells that are commonly connected to each other by a particular access line 202 might collectively be referred to as tiers.

The three-dimensional NAND memory array 200B might be formed over peripheral circuitry 226. The peripheral circuitry 226 might represent a variety of circuitry for accessing the memory array 200B. The peripheral circuitry 226 might include complementary circuit elements. For example, the peripheral circuitry 226 might include both n-channel region and p-channel region transistors formed on a same semiconductor substrate, a process commonly referred to as CMOS, or complementary metal-oxide-semiconductors. Although CMOS often no longer utilizes a strict metal-oxide-semiconductor construction due to advancements in integrated circuit fabrication and design, the CMOS designation generally remains as a matter of convenience.

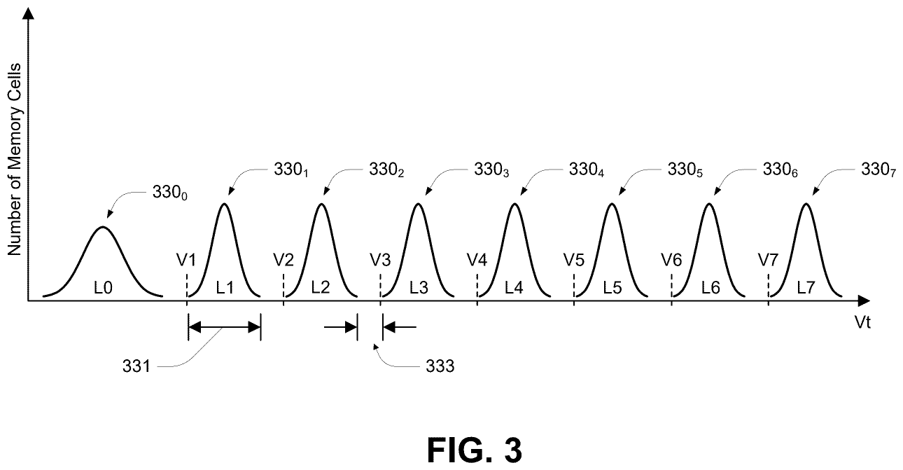

FIG. 3 is a conceptual depiction of threshold voltage distributions of a plurality of memory cells as could be used with embodiments. FIG. 3 illustrates an example of threshold voltage distributions and their threshold voltage ranges for a population of eight-level (e.g., three-bit) memory cells, often referred to as TLC memory cells. For example, such a memory cell might be programmed to a threshold voltage (Vt) that falls within one of eight different threshold voltage distributions 330₀-330₇, each being used to represent a data state corresponding to a bit pattern of three bits. The threshold voltage distribution 330₀ typically has a greater width than the remaining threshold voltage distributions 330₁-330₇ as memory cells are generally all placed in the data state corresponding to the threshold voltage distribution 330₀, then subsets of those memory cells are subsequently programmed to have threshold voltages in one of the threshold voltage distributions 330₁-330₇. As programming operations are often more incrementally controlled than erase operations, these threshold voltage distributions 330₁-330₇ might tend to have tighter distributions.

The threshold voltage distributions 330₀, 330₁, 330₂, 330₃, 330₄, 330₅, 330₆ and 330₇ might each represent a respective data state, e.g., L0, L1, L2, L3, L4, L5, L6 and L7, respectively. The threshold voltage distributions 330₁-330₇ might each have a width 331, e.g., a voltage difference between a highest voltage level and a lowest voltage level of the corresponding threshold voltage distribution 330. In addition, a dead space or margin 333 is typically maintained between adjacent threshold voltage distributions 330₁-330₇ during programming in order to mitigate subsequent overlapping of the threshold voltage distributions over time. The width 331 of any one threshold voltage distribution 330₁-330₇ might be the same or different than the width 331 of any other threshold voltage distribution 330₁-330₇. Similarly, the margin 333 between any pair of adjacent threshold voltage distributions 330 might be the same or different than the margin 333 between any remaining pair of adjacent threshold voltage distributions 330. The sum of the margins 333 for each of the threshold voltage distributions 330 might be referred to as a read window budget (RWB).

As depicted in FIG. 3, if the threshold voltage of a memory cell is within the first of the eight threshold voltage distributions 330₀, the memory cell in this case might be storing a data state L0 having a data value of logical 111 and is typically referred to as the erased state of the memory cell. If the threshold voltage is within the second of the eight threshold voltage distributions 330₁, the memory cell in this case might be storing a data state L1 having a data value of logical 011. If the threshold voltage is within the third of the eight threshold voltage distributions 330₂, the memory cell in this case might be storing a data state L2 having a data value of logical 001, and so on. Table 1 provides one possible correspondence between the data states and their corresponding logical data values. Other assignments of data states to logical data values are known. Memory cells remaining in the lowest data state (e.g., the erased state or L0 data state), as used herein, will be deemed to be programmed to the lowest data state.

TABLE 1

| Data State | Logical Data Value |
|---|---|
| L0 | 111 |
| L1 | 011 |
| L2 | 001 |
| L3 | 101 |
| L4 | 100 |
| L5 | 000 |
| L6 | 010 |
| L7 | 110 |

Program-verify voltage levels, or simply verify voltage levels, V1-V7 might be used to determine when a memory cell being programmed has reached a particular threshold voltage distribution 330₁-330₇, respectively. For example, a memory cell being programmed to the data state L1 might be enabled for programming for one or more programming pulses (e.g., one or more programming pulses of increasing voltage levels) of a programming operation until it can no longer be activated in response to a gate-source voltage equal to the verify voltage level V1, a memory cell being programmed to the data state L2 might be enabled for programming for one or more programming pulses of the programming operation until it can no longer be activated in response to a gate-source voltage equal to the verify voltage level V2, a memory cell being programmed to the data state L3 might be enabled for programming for one or more programming pulses of the programming operation until it can no longer be activated in response to a gate-source voltage equal to the verify voltage level V3, and so on.

Programming in memories is typically accomplished by applying one or more programming pulses, separated by verify pulses, to program each memory cell of a selected group of memory cells to a respective desired data state (which might be an interim or final data state). With such a technique, the programming pulses are applied to access lines, such as those typically referred to as word lines, for selected memory cells. After each programming pulse, a verify pulse of one or more verify voltage levels is typically used to verify the programming of the selected memory cells. Programming typically uses many programming pulses using an incremental step pulse programming (ISPP) technique, where each programming pulse is a single-level pulse that moves the memory cell threshold voltage by some amount, and each subsequent programming pulse is higher than its preceding programming pulse.

The programming pulses might be applied to a selected access line (e.g., word line) and thus to the control gates of the row of memory cells connected to the selected access line (e.g., having their control gates connected to the selected access line). Typical programming pulses might start at or near 13V and tend to increase in magnitude for each subsequent programming pulse application. While the program potential (e.g., voltage level of the programming pulse) is applied to the selected access line, an enable voltage, such as a reference potential (e.g., Vss, ground, or 0V), might be applied to the channels of memory cells selected for programming that have not yet reached a desired data state, i.e., those memory cells for which the programming operation is intended to shift their data state to some higher level. This might result in a charge transfer from the channel to the charge storage structures of these selected memory cells. For example, floating gates are typically charged through direct injection or Fowler-Nordheim tunneling of electrons from the channel to the floating gate, resulting in an increased threshold voltage in a programmed state.

An inhibit voltage level (e.g., Vcc) is typically applied to data lines which are selectively connected to a NAND string containing a memory cell that is connected to the selected access line and is not selected for, or is no longer selected for, programming. In addition to data lines selectively connected to memory cells already at their desired data state, these unselected data lines might further include data lines that are not addressed by the programming operation. For example, a logical page of data might correspond to memory cells connected to a particular access line and selectively connected to some particular subset of the data lines (e.g., every other data line), such that the remaining subset of data lines would be unselected for the programming operation and thus inhibited.

Between the application of one or more programming pulses, a verify phase of the programming operation is typically performed to check each selected memory cell to determine if it has reached its desired data state. If a selected memory cell has reached its desired data state, it might be inhibited from further programming if there remain other selected memory cells still requiring additional programming pulses to reach their desired data states. Following a verify phase, an additional programming pulse might be applied if there are memory cells that have not completed programming. This process of applying a programming pulse followed by verification (e.g., a programming phase and a verify, or sensing, phase of a programming operation) typically continues until all the selected memory cells have reached their desired data states. If a particular number of programming pulses (e.g., maximum number) have been applied, or a particular voltage level of a programming pulse (e.g., maximum voltage level) has been reached, and one or more selected memory cells still have not completed programming, those memory cells might be marked as defective, for example.

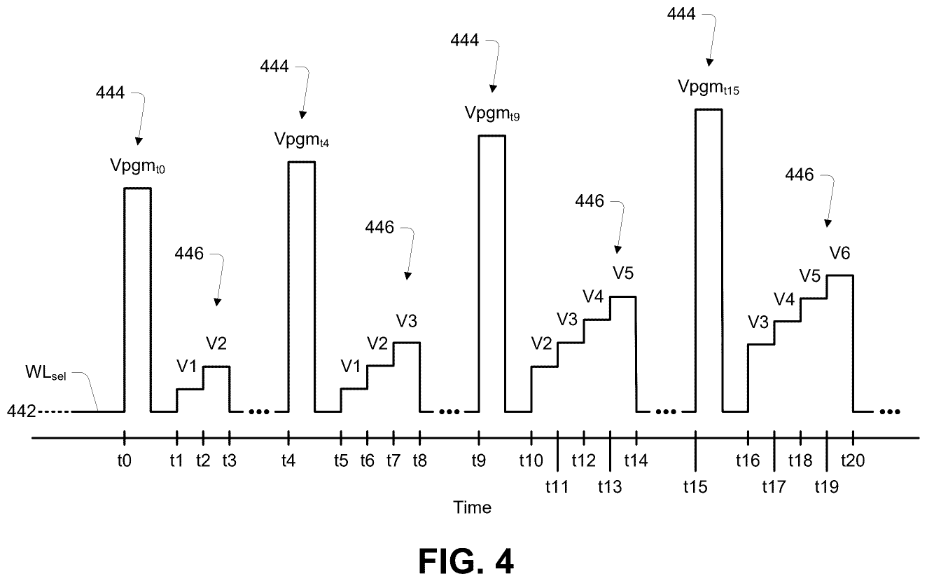

FIG. 4 is a timing diagram depicting voltage levels of a selected access line, e.g., access line 202ₓ, for a programming operation as could be used with embodiments. In FIG. 4, trace WLₛₑₗ might represent voltage levels applied to the selected access line. Prior to time t0, a reference potential 442, e.g., Vss, ground, or 0V, might be applied to the selected access line.

At time t0, a programming pulse 444 having a programming voltage level Vpgmₜ₀ might be applied to the selected access line. The programming voltage level Vpgmₜ₀ might correspond to a start programming voltage level of the programming operation. At time t1, a verify pulse 446 having the first verify voltage level V1 might be applied to the selected access line and the states of the data lines connected to selected memory cells having the desired data state L1 might be sensed, e.g., in manners well understood in the relevant art. Note that the states of data lines connected to selected memory cells having other desired data states might be sensed while applying the first verify voltage level V1 to the selected access line even though the sensed state might not be evaluated or relevant.

At time t2, the second verify voltage level V2 of the verify pulse 446 might be applied to the selected access line and the states of the data lines connected to selected memory cells having the desired data state L2 might be sensed. Remaining data states might not be evaluated as the voltage level of the preceding programming pulse 444 at time t0 might be deemed insufficient to program memory cells of higher data states, e.g., higher than data state L2. The time period t0-t1 might correspond to a programming phase of the programming operation, and the time period t1-t3 might correspond to a verify phase of the programming operation.

At time t4, a subsequent programming pulse 444 having a programming voltage level Vpgmₜ₄ might be applied to the selected access line. The programming voltage level Vpgmₜ₄ might be higher than the voltage level Vpgmₜ₀. It is noted that the subsequent programming pulse 444 need not be an immediately subsequent programming pulse 444, and that additional programming pulses 444 and additional verify pulse 446 might be applied to the selected access line between time t3 and time t4. At time t5, a verify pulse 446 having the first verify voltage level V1 might be applied to the selected access line and the states of the data lines connected to selected memory cells having the desired data state L1 might be sensed. At time t6, the second verify voltage level V2 of the verify pulse 446 might be applied to the selected access line and the states of the data lines connected to selected memory cells having the desired data state L2 might be sensed. At time t7, the third verify voltage level V3 of the verify pulse 446 might be applied to the selected access line and the states of the data lines connected to selected memory cells having the desired data state L3 might be sensed. Remaining data states might not be evaluated as the voltage level of the preceding programming pulse 444 at time t4 might be deemed insufficient to program memory cells of higher data states. The time period t4-t5 might correspond to a programming phase of the programming operation, and the time period t5-t8 might correspond to a verify phase of the programming operation.

At time t9, a subsequent programming pulse 444 having a programming voltage level Vpgmₜ₉ might be applied to the selected access line. The programming voltage level Vpgmₜ₉ might be higher than the programming voltage level Vpgmₜ₄. It is noted that the subsequent programming pulse 444 need not be an immediately subsequent programming pulse 444, and that additional programming pulses 444 and additional verify pulse 446 might be applied to the selected access line between time t8 and time t9. At time t10, a verify pulse 446 having the second verify voltage level V2 might be applied to the selected access line and the states of the data lines connected to selected memory cells having the desired data state L2 might be sensed. The first verify voltage level V1 might not be applied to the selected access line as it might have been determined, or deemed, that all memory cells intended for the data state L1 have reached their desired data state. At time t11, the third verify voltage level V3 of the verify pulse 446 might be applied to the selected access line and the states of the data lines connected to selected memory cells having the desired data state L3 might be sensed. At time t12, the fourth verify voltage level V4 of the verify pulse 446 might be applied to the selected access line and the states of the data lines connected to selected memory cells having the desired data state L4 might be sensed. At time t14, the fifth verify voltage level V5 of the verify pulse 446 might be applied to the selected access line and the states of the data lines connected to selected memory cells having the desired data state L5 might be sensed. Remaining data states might not be evaluated as the voltage level of the preceding programming pulse 444 might be deemed insufficient to program memory cells of higher data states. The time period t9-t10 might correspond to a programming phase of the programming operation, and the time period t10-t14 might correspond to a verify phase of the programming operation.

At time t15, a subsequent programming pulse 444 having a programming voltage level Vpgmₜ₁₅ might be applied to the selected access line. The programming voltage level Vpgmₜ₁₅ might be higher than the programming voltage level Vpgmₜ₉. It is noted that the subsequent programming pulse 444 need not be an immediately subsequent programming pulse 444, and that additional programming pulses 444 and additional verify pulses 446 might be applied to the selected access line between time t14 and time t15. At time t16, a verify pulse 446 having the third verify voltage level V3 might be applied to the selected access line and the states of the data lines connected to selected memory cells having the desired data state L3 might be sensed. The first verify voltage level V1 and the second verify voltage level V2 might not be applied to the selected access line as it might have been determined, or deemed, that all memory cells intended for the data state L1 and for the data state L2 have reached their desired data state. At time t17, the fourth verify voltage level V4 of the verify pulse 446 might be applied to the selected access line and the states of the data lines connected to selected memory cells having the desired data state L4 might be sensed. At time t18, the fifth verify voltage level V5 of the verify pulse 446 might be applied to the selected access line and the states of the data lines connected to selected memory cells having the desired data state L5 might be sensed. At time t19, the sixth verify voltage level V6 of the verify pulse 446 might be applied to the selected access line and the states of the data lines connected to selected memory cells having the desired data state L6 might be sensed. Remaining data states might not be evaluated as the voltage level of the preceding programming pulse 444 might be deemed insufficient to program memory cells of higher data states. The time period t15-t16 might correspond to a programming phase of the programming operation, and the time period t16-t20 might correspond to a verify phase of the programming operation. Subsequent to time t20, the programming operation might continue until completion (e.g., all selected memory cells reaching their desired data state) in a similar manner, or until a failure is deemed to occur.

Although a decision process was described to avoid performing a verification for each data state following a programming pulse 444, other embodiments could perform a verification for each data state following a programming pulse 444, applying verify pulses 446 having verify voltage levels V1-V7 after each programming pulse 444. Similarly, fewer or more verifications might be performed following a programming pulse 444 than are explicitly depicted in FIG. 4.

Each programming pulse 444 of a programming operation might generally be higher than each preceding programming pulse 444. In many cases, the programming voltage level of each programming pulse 444 is higher than the programming voltage level of its immediately preceding programming pulse 444 by a predetermined ΔV. The predetermined ΔV might be the same for each programming pulse 444 of a programming operation. Alternatively, the predetermined ΔV for some adjacent programming pulses 444 of a programming operation might be different than the predetermined ΔV for other adjacent programming pulses 444 of the programming operation. For example, a first ΔV might be used for a first number of programming pulses 444 of a programming operation, and a second ΔV, lower than the first ΔV, might be used for a subsequent number of programming pulses 444 of the programming operation.

Although each programming pulse was depicted to increase from the reference potential to its respective programming voltage level Vpgm, the voltage level of the selected access line might typically increase from the reference potential to a pass voltage level Vpass (e.g., a control gate voltage level configured to activate a memory cell regardless of its threshold voltage), while concurrently increasing the voltage level of one or more unselected access lines to the pass voltage level Vpass, then subsequently increasing to the programming voltage level Vpgm. Such operation might allow all access lines (e.g., selected and unselected access lines) to reach a steady-state voltage level more quickly.

While an ISPP technique might facilitate narrow threshold voltage distributions, it has been noted that the average threshold voltage shift of memory cells being programmed might be larger for an initial programming pulse, and subsequently smaller as additional programming pulses are applied and the memory cells reach a balanced state. In order to reach this balanced state more quickly, one or more equilibrium pulses, e.g., initial programming pulses configured to quickly bring the memory cells to a balanced state, might be applied prior to performing an ISPP technique. An equilibrium pulse might generally use a higher voltage level than an initial programming pulse of the ISPP phase of the programming operation. During an equilibrium pulse, it is typical that fewer than all memory cells having a desired data state higher than the lowest data state might be enabled for programming. Considering the example of TLC memory cells, L3-L7 memory cells might be enabled for programming during a first equilibrium pulse of the related art, and L5-L7 memory cells might be enabled for programming during a second equilibrium pulse of the related art. This might result in a reduction of the average difference between the respective verify voltage level corresponding to each memory cell's desired data state and its respective threshold voltage. Use of one or more equilibrium pulses might reduce a total number of programming pulses required to attain an equivalent RWB over use of ISPP alone.

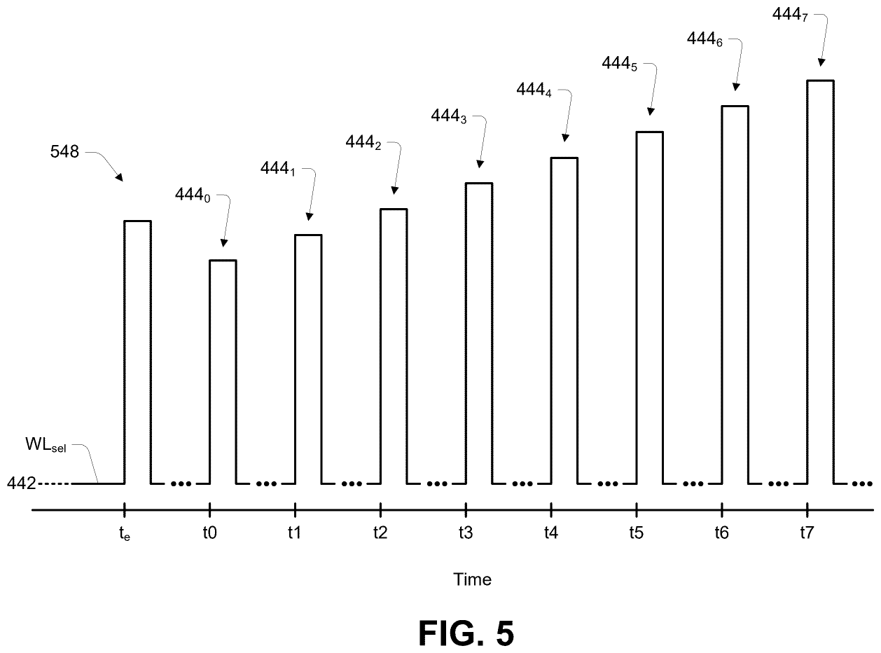

FIG. 5 is a timing diagram depicting voltage levels of a selected access line, e.g., access line 202ₓ, for a programming operation as could be used with embodiments. In FIG. 5, trace WLₛₑₗ might represent voltage levels applied to the selected access line. FIG. 5 depicts a programming operation including an equilibrium pulse phase followed by an ISPP phase. For simplicity, the application of any verify pulses are not depicted in FIG. 5. Prior to time tₑ, a reference potential 442, e.g., Vss, ground, or 0V, might be applied to the selected access line.

At time tₑ, an equilibrium pulse 548 might be applied to the selected access line. The equilibrium pulse 548 might be an initial programming pulse of the programming operation. Although permissible, there may be no verifications performed after applying the equilibrium pulse 548 and prior to applying a subsequent programming pulse 444 (or another equilibrium pulse 548). Fewer than all memory cells selected for programming, and having desired data states higher than a lowest data state of a plurality of possible data states for the programming operation, might be enable for programming during application of the equilibrium pulse 548. In addition, each memory cell enabled for programming during application of the equilibrium pulse 548 might be enabled for programming to a same extent, e.g., fully enabled for programming. The time period tₑ-t0 might correspond to an equilibrium phase of the programming operation.

At time t0, a programming pulse 444₀ might be applied to the selected access line. The programming pulse 444₀ might be an initial programming pulse of an ISPP phase of the programming operation. The programming pulse 444₀ might have a start programming voltage level of the programming operation that is lower than the programming voltage level of the equilibrium pulse 548. In addition, the equilibrium pulse 548 might have a higher programming voltage level than one or more additional programming pulses 444, e.g., 444₁-444₇. A verify phase of the programming operation might occur after the programming pulse 444₀ and prior to time t1 for one or more of the possible data states. At time t1, a subsequent programming pulse 444₁ might be applied to the selected access line. The programming voltage level of the programming pulse 444₁ might be higher than the voltage level of the programming pulse 444₀.

A verify phase of the programming operation might occur after the programming pulse 444₁ and prior to time t2 for one or more of the possible data states. At time t2, a subsequent programming pulse 444₂ might be applied to the selected access line. The programming voltage level of the programming pulse 444₂ might be higher than the programming voltage level of the programming pulse 444₁. A verify phase of the programming operation might occur after the programming pulse 444₂ and prior to time t3 for one or more of the possible data states. At time t3, a subsequent programming pulse 444₃ might be applied to the selected access line. The programming voltage level of the programming pulse 444₃ might be higher than the programming voltage level of the programming pulse 444₂. Subsequent to applying the programming pulse 444₃, the programming operation might continue until completion in a similar manner, or until a failure is deemed to occur. The time period t0 and beyond might correspond to an ISPP phase (e.g., including one or more programming phases and one or more verify phases) of the programming operation.

Various embodiments seek to facilitate the advantages of equilibrium pulse programming while further reducing the total number of programming pulses needed to complete programming and/or improving RWB over traditional equilibrium pulse programming. Various embodiments might further attain an equivalent or improved distribution of threshold voltages using a same or lesser number of equilibrium pulses. In particular, various embodiments might utilize boosted channel programming techniques in an equilibrium pulse to concurrently move the threshold voltages of memory cells of multiple subsets of data states to different extents toward the threshold voltage ranges of their respective desired threshold voltage distributions.

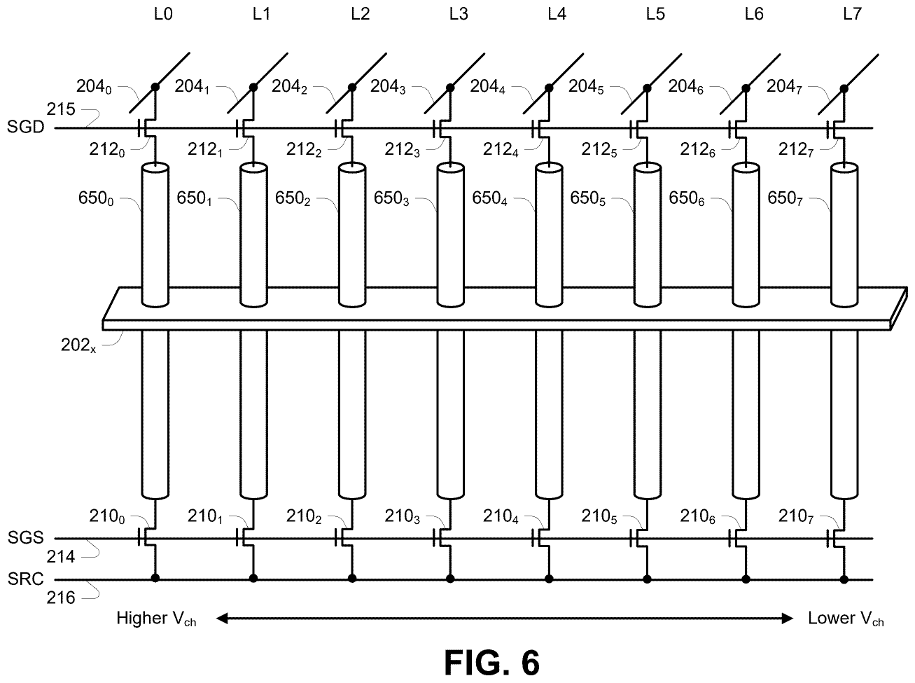

Consider the example of a TLC memory having eight memory cells, each having a desired data state corresponding to a respective one of the possible data states of TLC memory cells, e.g., data states L0-L7. FIG. 6 depicts a modified schematic of a portion of an array of memory cells as could be used in a memory of the type described with reference to FIG. 1. Like numbered elements in FIG. 6 correspond to the description as provided with respect to FIG. 2A. For clarity, only a selected access line 202ₓ is depicted in FIG. 6. In addition, GIDL generator gates and individual memory cells are similarly not depicted.

In FIG. 6, the selected access line 202ₓ is depicted to intersect with the pillars 650, e.g., pillars 650₀-650₇. Each pillar 650 might be a conductively-doped semiconductor pillar, for example, whether hollow or solid. A portion of each pillar 650 might act as a channel of memory cells formed at its intersection with each access line. In the example of FIG. 6, a memory cell formed at an intersection of the pillar 650₀ and the selected access line 202ₓ might have a desired data state of L0 for a programming operation, a memory cell formed at an intersection of the pillar 650₁ and the selected access line 202ₓ might have a desired data state of L1 for the programming operation, a memory cell formed at an intersection of the pillar 650₂ and the selected access line 202ₓ might have a desired data state of L2 for the programming operation, a memory cell formed at an intersection of the pillar 650₃ and the selected access line 202ₓ might have a desired data state of L3 for the programming operation, a memory cell formed at an intersection of the pillar 650₄ and the selected access line 202ₓ might have a desired data state of L4 for the programming operation, a memory cell formed at an intersection of the pillar 650₅ and the selected access line 202ₓ might have a desired data state of L5 for the programming operation, a memory cell formed at an intersection of the pillar 650₆ and the selected access line 202ₓ might have a desired data state of L6 for the programming operation, and a memory cell formed at an intersection of the pillar 650₇ and the selected access line 202ₓ might have a desired data state of L7 for the programming operation.

Boosted channel programming traditionally seeks to develop differing voltage levels in the channel of selected memory cells of differing desired data states prior to applying the programming voltage level of a programming pulse. Continuing with the example, the voltage level of the channels of each selected memory cell, e.g., V_{ch}, might be the highest for a selected memory cell having the lowest desired data state, e.g., L0 (or having previously been determined to pass verification), and might be the lowest for a selected memory cell having the highest desired data state, e.g., L7. This leads to higher gate-to-body voltage differentials for memory cells having higher data states than memory cells having lower data states, such that memory cells having higher data states might be expected to have a larger threshold voltage change (e.g., larger charge accumulation) than memory cells having lower data states in response to a same control gate voltage level.

In contrast to traditional boosted channel programming, where each possible data state of the programming operation is associated with a different channel voltage level, various embodiments might seek to associate multiple possible data states of the programming operation with a same channel voltage level. By doing so, improvements over using traditional equilibrium pulse programming might be facilitated while facilitating a reduced programming time over using traditional boosted channel programming techniques by not developing different channel voltage levels for each possible data state.

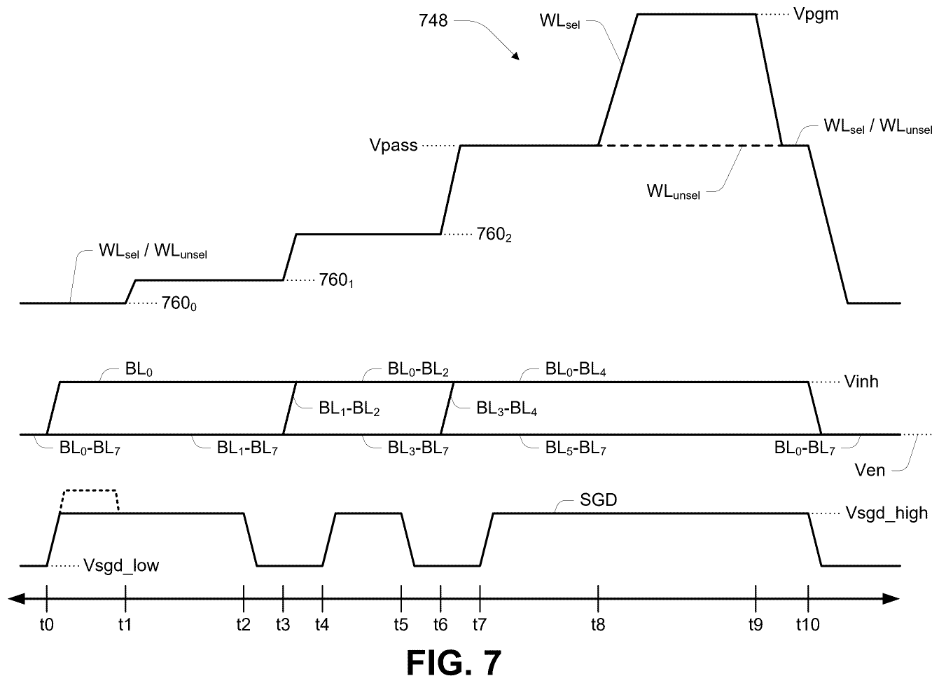

FIG. 7 illustrates a timing diagram for an equilibrium pulse 748 of a programming operation in accordance with an embodiment. The example of FIG. 7 describes a programming operation for TLC memory cells, but the concepts can be applied to the programming of higher or lower numbers of digits per memory cell. The process will be described with reference to an array architecture of the types depicted in FIGS. 2A and 6, and with reference to data states such as depicted in FIG. 3. The process will generally refer to a selected access line (e.g., selected word line) that is connected to one or more memory cells selected for programming and an unselected access line (e.g., unselected word line) that is connected to one or more memory cells not selected for programming, e.g., not connected to any memory cell selected for programming. Voltage levels applied to the selected access line are represented by the trace WLₛₑₗ while voltage levels applied to the unselected access line are represented by trace WLᵤₙₛₑₗ. Although only one unselected access line is discussed with reference to FIG. 7, one or more additional (e.g., including up to all) unselected access lines of a NAND string 206 might receive the same voltage levels, although other schemes might also be used.

The process of FIG. 7 might also generally refer to selected data lines 204 (e.g., selected bit lines) each selectively connected to a memory cell selected for programming to one of the L1-L7 data states, and unselected data lines 204 (e.g., unselected bit lines) that are selectively connected to memory cells connected to the selected access line that are to remain in the L0 data state. Voltage levels applied to the selected data lines 204 for data states L1-L7 are represented by traces BL₁-BL₇, respectively, while voltage levels applied to the unselected data lines 204 for data state L0 are represented by trace BL₀. The voltage levels applied to the select gate drain 215, and thus to the drain select gates 212, are represented by trace SGD. The voltage levels applied to the select gate source 214 (not depicted in FIG. 7) might be configured to deactivate the corresponding source select gates 210, throughout the relevant time periods of FIG. 7.

Prior to time t0, the voltage level applied to WLₛₑₗ and WLᵤₙₛₑₗ might be at a voltage level 760₀, which might be the reference potential, although other voltage levels might be used to attain desired levels of channel boosting during the equilibrium pulse 748. The voltage level applied to BL₀-BL₇ (e.g., data lines 204₀-204₇, respectively) might be at an enable voltage level Ven, which might be the reference potential, although other voltage levels might be used to attain desired activation or deactivation of the drain select gates in response to the voltage levels applied to SGD. And the voltage level applied to SGD might be at a voltage level Vsgd_low, which might be the reference potential, although other voltage levels might be used to attain deactivation of the drain select gates.

At time t0, the voltage level applied to the BL₀ might be increased to an inhibit voltage level Vinh (e.g., Vcc) while the voltage level applied to BL₁-BL₇ remains at the enable voltage level Ven. In conjunction, the voltage level applied to SGD might be increased to a voltage level Vsgd_high. This might electrically float the respective channels of the memory cells having the L0 desired data state, and apply the enable voltage level Ven to the respective channels of the memory cells having any of the L1-L7 data states.

As depicted in dashed line, the voltage level applied to SGD might alternatively be increased to a voltage level higher than Vsgd_high that might be sufficient to activate the corresponding select gates to pass the voltage level of BL₀ to the channels of the corresponding NAND strings connected to the selected access line before being decreased to Vsgd_high before time t1. The voltage level Vsgd_high might be a voltage level sufficient to activate select gates 212 connected to data lines to which the enable voltage level Ven is applied and to deactivate select gates 212 connected to data lines to which the inhibit voltage level Vinh is applied.

At time t1, the voltage level applied to WLₛₑₗ and WLᵤₙₛₑₗ might be increased to a voltage level 760₁, boosting the channel voltage (Vch) of the memory cells connected to the selected access line that are to remain at the L0 data state, e.g., through capacitive coupling. At time t2 (e.g., after WLₛₑₗ and WLᵤₙₛₑₗ have reached the voltage level 760₁), the voltage level applied to SGD might be decreased to the voltage level Vsgd_low. This might serve to lock the respective channel voltage levels for each data state L0-L7 (e.g., the channel voltage levels of the pillars 650₀-650₇, respectively) before any changes are made to data line voltage levels by isolating each NAND string from its corresponding data line and electrically floating their respective channels. Alternatively, the voltage level applied to SGD might remain at the voltage level Vsgd_high at time t2.

At time t3, the voltage level applied to WLₛₑₗ and WLᵤₙₛₑₗ might be increased to a voltage level 760₂, further boosting the channel voltage of the memory cells connected to the selected access line that are to remain at the L0 data state. If SGD is decreased to Vsgd_low at time t2, the voltage level applied to BL₁ and BL₂ might be increased to the inhibit voltage level Vinh between times t2 and t4, and might be increased concurrently with the increase of the voltage level applied to Wlₛₑₗ and WLᵤₙₛₑₗ at time t3. If the voltage level applied to SGD is alternatively maintained at Vsgd_high at time t2, the voltage level applied to BL₁ and BL₂ might be increased to the inhibit voltage level Vinh prior to time t3 (e.g., after time t1 and prior to time t3) in order to isolate the NAND strings corresponding to the L1 and L2 data states from their corresponding data lines prior to increasing the voltage level applied to Wlₛₑₗ and WLᵤₙₛₑₗ at time t3. In either case, the increase of WLₛₑₗ and WLᵤₙₛₑₗ to the voltage level 760₂ might boost the channel voltage of the memory cells connected to the selected access line that have L1 and L2 desired data states. At time t4, SGD might be returned to the voltage level Vsgd_high. While channel voltages of memory cells connected to the selected access line that have the L3-L7 data states might be boosted at time t3 if SGD is at the voltage level Vsgd_low, these channels might be expected to discharge back to the enable voltage level Ven at time t4 upon being reconnected to their respective data lines.

At time t5, the voltage level applied to SGD might be decreased to the voltage level Vsgd_low. This might serve to lock the respective channel voltage levels for each data state L0-L7 (e.g., the channel voltage levels of the pillars 650₀-650₇, respectively) before any changes are made to data line voltage levels by isolating each NAND string from its corresponding data line. Alternatively, the voltage level applied to SGD might remain at the voltage level Vsgd_high at time t5.

At time t6, the voltage level applied to WLₛₑₗ and WLᵤₙₛₑₗ might be increased to a pass voltage level Vpass, further boosting the channel voltage of the memory cells connected to the selected access line that have the L0-L2 desired data states. If the voltage level applied to SGD is decreased to Vsgd_low at time t5, the voltage level applied to BL₃ and BL₄ might be increased to the inhibit voltage level Vinh between times t5 and t7, and might be increased concurrently with the increase of BL₃ and BL₄. If SGD is alternatively maintained at Vsgd_high at time t5, BL₃ and BL₄ might be increased to the inhibit voltage level Vinh prior to time t6 (e.g., after time t4 and prior to time t6) in order to isolate the NAND strings corresponding to the L3 and L4 data states from their corresponding data lines prior to increasing the voltage level applied to Wlₛₑₗ and WLᵤₙₛₑₗ at time t6. In either case, the increase of WLₛₑₗ and WLᵤₙₛₑₗ to the pass voltage level Vpass might boost the channel voltage of the memory cells connected to the selected access line that have L3 and L4 desired data states. At time t7, SGD might be returned to the voltage level Vsgd_high. While channel voltages of memory cells connected to the selected access line that have the L5-L7 data states might be boosted at time t6 if SGD is at the voltage level Vsgd_low, these channels might be expected to discharge back to the enable voltage level Ven at time t7 upon being reconnected to their respective data lines.

At time t8, the voltage level applied to WLₛₑₗ might be increased to a programming voltage level Vpgm while maintaining the voltage level applied to WLᵤₙₛₑₗ at the pass voltage level Vpass. As a result, a first subset of memory cells (e.g., memory cells having the L5, L6, and L7 desired data states) might be fully enabled for programming with a first gate-to-body voltage differential, a second subset of memory cells (e.g., memory cells having the L3 and L4 desired data states) might be partially enabled for programming with a second gate-to-body voltage differential less than the first gate-to-body voltage differential, a third subset of memory cells (e.g., memory cells having the L1 and L2 desired data states) might be partially enabled for programming with a third gate-to-body voltage differential less than the second gate-to-body voltage differential, and a fourth subset of memory cells (e.g., memory cells having the L0 desired data state) might be inhibited from programming with a fourth gate-to-body voltage differential, less than the third gate-to-body voltage differential.

At time t9, the voltage level applied to WLₛₑₗ might be decreased to the pass voltage level Vpass while maintaining the voltage level applied to WLᵤₙₛₑₗ at the pass voltage level Vpass. At time t10, WLₛₑₗ, WLᵤₙₛₑₗ, BL₀-BL₄, and SGD might be returned to their initial voltage levels. Subsequent to time t10, one or more additional equilibrium pulses might be applied in a similar manner. Alternatively, or in addition, an ISPP phase of the programming operation might be initiated to complete the programming of the selected memory cells of the programming operation, such as described with reference to FIGS. 4 and 5. An ISPP phase of the programming operation, or other programming technique, might be utilized after applying the equilibrium pulse 748 and without any intervening verify phase being performed.

The voltage levels 706₀, 760₁ and 760₂, and the programming voltage level Vpgm, might be determined for the equilibrium pulse either experimentally, empirically or through simulation. The voltage levels might be chosen in order to produce a desired shift in threshold voltages of the various subsets of memory cells selected for the programming operation. Although only one equilibrium pulse 748 is depicted in FIG. 7, one or more additional equilibrium pulses might be applied in a similar manner, but having increasingly higher programming voltage levels for each successive equilibrium pulse.

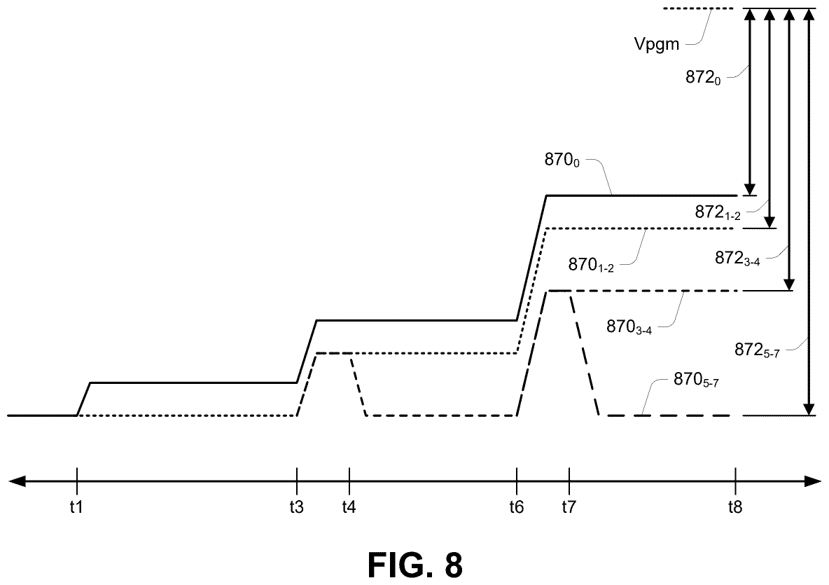

FIG. 8 is a timing diagram depicting channel voltage levels that might result from the application of the equilibrium pulse 748 of FIG. 7. Times referenced in FIG. 8 correspond to the times discussed in FIG. 7. FIG. 8 might represent the channel voltage levels for embodiments decreasing the voltage level applied to SGD to the voltage level Vsgd_low at times t2 and t5, and subsequently returning it to Vsgd_high at times t4 and t7, respectively.

The trace 870₀ might represent the channel voltage level of the fourth subset of memory cells connected to the selected access line that are to remain at the L0 data state, the trace 870₁₋₂ might represent the channel voltage level of the third subset of memory cells connected to the selected access line that have the L1 or L2 desired data state, the trace 870₃₋₄ might represent the channel voltage level of the second subset of memory cells connected to the selected access line that have the L3 or L4 desired data state, and the trace 870₅₋₇ might represent the channel voltage level of the first subset of memory cells connected to the selected access line that have the L5, L6, or L7 desired data state.

Although data intended for programming to memory cells might not include similarly sized distributions of each of the possible data states, and might be devoid of one or more of the data states, it is typical to utilize data randomization prior to programming such that the data programmed to the memory cells might approach a random distribution of all of the possible data states. Data randomization is often used to mitigate coupling effects between closely neighboring memory cells that can disturb the intended data states. As a result of data randomization, each possible data state to which a memory cell can be programmed in a programming operation might be programmed to a similar (e.g., the same) number of memory cells. As such, while any of the subsets of memory cells could contain a number of memory cells ranging from zero to a total number of memory cells selected for a programming operation, each subset of memory cells would typically contain a number of memory cells that is proportional to its corresponding number of data states. For example, if 4K (e.g., 4096) memory cells are each programmed to one of eight possible data states (e.g., data states L0-L7) utilizing data randomization, the fourth subset of memory cells might be expected to contain a number of memory cells substantially equal to (e.g., equal to) 512 memory cells, the third subset of memory cells might be expected to contain a number of memory cells substantially equal to (e.g., equal to) 1024 memory cells, the second subset of memory cells might be expected to contain a number of memory cells substantially equal to (e.g., equal to) 1024 memory cells, and the first subset of memory cells might be expected to contain a number of memory cells substantially equal to (e.g., equal to) 1536 memory cells.

As depicted in FIG. 8, the different channel voltage levels for the different subsets of memory cells might produce different gate-to-body voltage differentials 872. For example, the fourth subset of memory cells connected to the selected access line that are to remain at the L0 data state might have a first gate-to-body voltage differential 872₀, the third subset of memory cells connected to the selected access line that have the L1 or L2 desired data state might have a second gate-to-body voltage differential 872₁₋₂ greater than the first gate-to-body voltage differential 872₀, the second subset of memory cells connected to the selected access line that have the L3 or L4 desired data state might have a third gate-to-body voltage differential 872₃₋₄ greater than the second gate-to-body voltage differential 872₁₋₂, and the first subset of memory cells connected to the selected access line that have the L5, L6, or L7 desired data state might have a fourth gate-to-body voltage differential 872₅₋₇ greater than the third gate-to-body voltage differential 872₃₋₄. The differing gate-to-body voltage differentials might be expected to affect the threshold voltages of the various memory cells selected for the programming operation to different degrees.

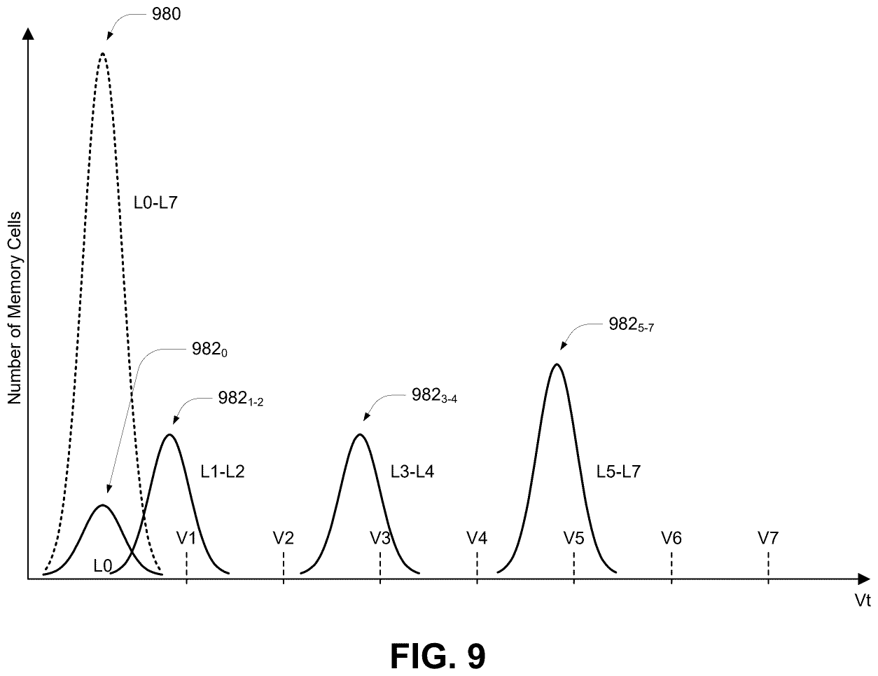

FIG. 9 is a conceptual depiction of threshold voltage distributions of a plurality of memory cells that might result from the application of an equilibrium pulse in accordance with an embodiment. In FIG. 9, the threshold voltage distribution 980 might represent the threshold voltage distribution of a plurality of memory cells selected for programming to one of a plurality of possible data states (e.g., to one of the data states L0-L7), but prior to programming, e.g., with each memory cell of the plurality of memory cells in the erased data state. Following application of an equilibrium pulse such as described with reference to FIG. 7, the fourth subset of memory cells connected to the selected access line that are to remain at the L0 data state might remain at the L0 data state as represented by the threshold voltage distribution 982₀ due to being inhibited from programming. The third subset of memory cells connected to the selected access line that have the L1 or L2 desired data state might shift to the threshold voltage distribution 982₁₋₂ that might be higher than a threshold voltage range corresponding to the L0 data state (e.g., threshold voltage range 330₀ of FIG. 3), but is lower than or equal to a threshold voltage range corresponding to the L1 data state (e.g., threshold voltage range 330₁ of FIG. 3) due to being partially enabled for programming. The second subset of memory cells connected to the selected access line that have the L3 or L4 desired data state might shift to the threshold voltage distribution 982₃₋₄ that might be higher than a threshold voltage range corresponding to the L2 data state (e.g., threshold voltage range 330₂ of FIG. 3), but is lower than or equal to a threshold voltage range corresponding to the L3 data state (e.g., threshold voltage range 330₃ of FIG. 3) due to being partially enabled for programming to a higher degree than the third subset of memory cells. The first subset of memory cells connected to the selected access line that have the L5, L6, or L7 desired data state might shift to the threshold voltage distribution 982₅₋₇ that might be higher than a threshold voltage range corresponding to the L4 data state (e.g., threshold voltage range 330₄ of FIG. 3), but is lower than or equal to a threshold voltage range corresponding to the L5 data state (e.g., threshold voltage range 330₅ of FIG. 3) due to being fully enabled for programming, e.g., enabled to a higher degree than the second subset of memory cells.

In general, a threshold voltage distribution 982 might have a highest threshold voltage level that is lower than a next higher verify voltage level than the verify voltage level corresponding to the lowest desired data state of its corresponding subset of memory cells. A threshold voltage distribution 982 further might have a lowest threshold voltage level that is lower than or equal to the verify voltage level corresponding to the lowest desired data state of its corresponding subset of memory cells. For example, the threshold voltage distribution 982₀ might have a highest threshold voltage level that is lower than the verify voltage level V1 corresponding to the data state L1, the threshold voltage distribution 982₁₋₂ might have a highest threshold voltage level that is lower than the verify voltage level V2 corresponding to the data state L2 and might have a lowest threshold voltage level that is lower than or equal to the verify voltage level V1 corresponding to the data state L1, the threshold voltage distribution 982₃₋₄ might have a highest threshold voltage level that is lower than the verify voltage level V4 corresponding to the data state L4 and might have a lowest threshold voltage level that is lower than or equal to the verify voltage level V3 corresponding to the data state L3, and the threshold voltage distribution 982₅₋₇ might have a highest threshold voltage level that is lower than the verify voltage level V6 corresponding to the data state L6 and might have a lowest threshold voltage level that is lower than or equal to the verify voltage level V5 corresponding to the data state L5.

The threshold voltage distributions 982 each might be deemed to be unimodal. It is recognized that different operating characteristics of different memory cells within a subset of memory cells might result in a threshold voltage distribution 982 that is in fact multimodal, but it will be deemed to be unimodal if there is no intentional act taken during the programming operation to alter the threshold voltage of a memory cell of that subset of memory cells having one desired data state to a different extent than if that memory cell had a different desired data state of that subset of memory cells. For example, with reference to the first subset of memory cells of the example of FIGS. 7-9, the threshold voltage distribution 982₅₋₇ would be deemed to be unimodal if no intentional act is taken during the programming operation to increase the threshold voltage of a memory cell having the L5 desired data state to a different extent than if it were to have the L6 or L7 desired data state. Intentional acts might include the use of different channel voltage levels for different data states within a subset of memory cells, different verify voltages for different data states within a subset of memory cells, different gate voltages for different data states within a subset of memory cells, etc.

Following application of one or more equilibrium pulses in accordance with embodiments, the memory cells might be further programmed to their desired data states from their respective threshold voltage distributions 982. For example, the L1 memory cells of the threshold voltage distribution 982₁₋₂ might be further programmed to shift their threshold voltages to fall within the threshold voltage distribution 330₁ corresponding to their desired data state, the L2 memory cells of the threshold voltage distribution 982₁₋₂ might be further programmed to shift their threshold voltages to fall within the threshold voltage distribution 330₂ corresponding to their desired data state, the L3 memory cells of the threshold voltage distribution 982₃₋₄ might be further programmed to shift their threshold voltages to fall within the threshold voltage distribution 330₃ corresponding to their desired data state, the L4 memory cells of the threshold voltage distribution 982₃₋₄ might be further programmed to shift their threshold voltages to fall within the threshold voltage distribution 330₄ corresponding to their desired data state, the L5 memory cells of the threshold voltage distribution 982₅₋₇ might be further programmed to shift their threshold voltages to fall within the threshold voltage distribution 330₅ corresponding to their desired data state, the L6 memory cells of the threshold voltage distribution 982₅₋₇ might be further programmed to shift their threshold voltages to fall within the threshold voltage distribution 330₆ corresponding to their desired data state, and the L7 memory cells of the threshold voltage distribution 982₅₋₇ might be further programmed to shift their threshold voltages to fall within the threshold voltage distribution 330₇ corresponding to their desired data state. This further programming might utilize a different programming technique from the equilibrium pulse, such as ISPP, although other known programming techniques might alternatively be used to complete the programming, e.g., shifting threshold voltages of all selected memory cells of the programming operation to their corresponding desired range of threshold voltages.

For various embodiments, a plurality of memory cells selected for a programming operation might be divided into three or more subsets of memory cells, e.g., as a plurality of subsets of memory cells selected for the programming operation. At least one of the subsets of memory cells might include memory cells of two or more data states, e.g., two or more adjacent data states. The subsets of memory cells might further be mutually exclusive as to contained data states. While the example of FIGS. 7-9 described a TLC programming operation and divided the selected memory cells into four subsets of memory cells corresponding to L0 memory cells, L1-L2 memory cells, L3-L4 memory cells, and L5-L7 memory cells, other groupings are possible. For example, the subsets could be L0-L1 memory cells, L2-L4 memory cells, and L5-L7 memory cells, or L0 memory cells, L1-L3 memory cells, and L4-L7 memory cells, or any other combinations and numbers of subsets meeting the criteria. Similar groupings might be used for QLC memory. One example might divide its memory cells into five subsets of memory cells, containing L0 memory cells, L1-L4 memory cells, L5-L8 memory cells, L9-L12 memory cells, and L13-L15 memory cells. These concepts can also be applied to lower memory densities, with one example of MLC memory having three subsets of memory cells, containing L0 memory cells, L1-L2 memory cells, and L3 memory cells.

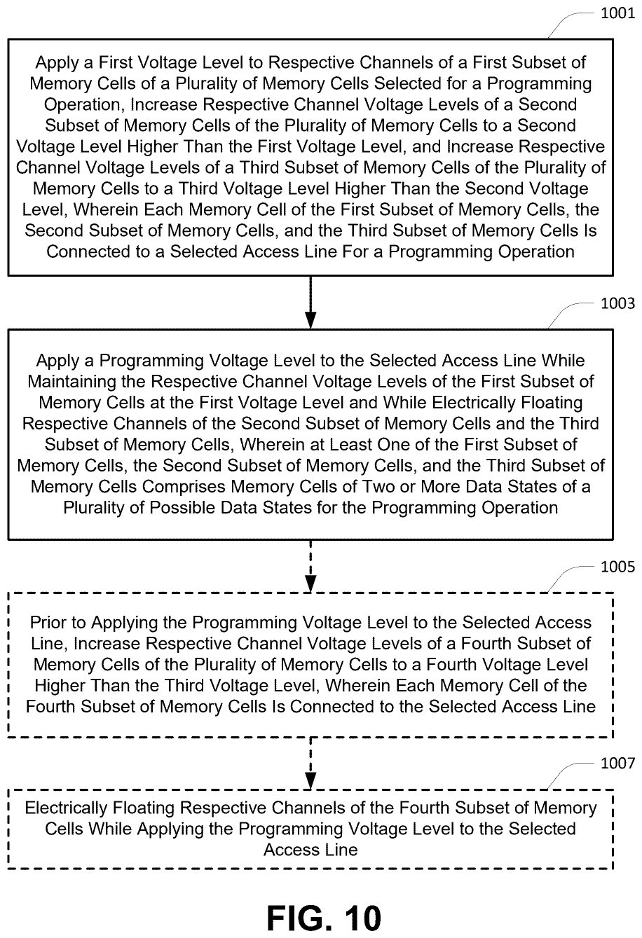

FIG. 10 is a flowchart of a method of operating a memory in accordance with an embodiment. The method might represent actions associated with a programming operation performed by the memory. The method might be in the form of computer-readable instructions, e.g., stored to the instruction registers 128. Such computer-readable instructions might be executed by a controller, e.g., the control logic 116, to cause the relevant components of the memory to perform the method.

At 1001, a first voltage level might be applied to respective channels of a first subset of memory cells of a plurality of memory cells selected for a programming operation, respective channel voltage levels of a second subset of memory cells of the plurality of memory cells might be increased to a second voltage level higher than the first voltage level, and respective channel voltage levels of a third subset of memory cells of the plurality of memory cells might be increased to a third voltage level higher than the second voltage level. Each memory cell of the first subset of memory cells, the second subset of memory cells, and the third subset of memory cells might be connected to a selected access line for a programming operation. Each subset of memory cells might be mutually exclusive of each remaining subset of memory cells. A union of the first subset of memory cells, the second subset of memory cells, and the third subset of memory cells might contain all memory cells of the plurality of memory cells selected for the programming operation. For example, the first subset of memory cells might include L3 memory cells of an MLC memory, the second subset of memory cells might include L1 and L2 memory cells of the MLC memory, and the third subset of memory cells might include L0 memory cells of the MLC memory. Alternatively, the union of the first subset of memory cells, the second subset of memory cells, and the third subset of memory cells might contain fewer than all memory cells of the plurality of memory cells selected for the programming operation. For example, the first subset of memory cells might include L5-L7 memory cells of a TLC memory, the second subset of memory cells might include L3 and L4 memory cells of the TLC memory, and the third subset of memory cells might include L1 and L2 memory cells of the TLC memory. As a still further example, the first subset of memory cells might include L13-L15 memory cells of a QLC memory, the second subset of memory cells might include L10-L12 memory cells of the QLC memory, and the third subset of memory cells might include L7-L9 memory cells of the QLC memory. For such embodiments, additional subsets of memory cells selected for the programming operation might be acted upon, as discussed later.

At 1003, a programming voltage level might be applied to the selected access line while maintaining the respective channel voltage levels of the first subset of memory cells at the first voltage level and while electrically floating respective channels of the second subset of memory cells and the third subset of memory cells. A programming voltage level is a voltage level that would be expected to increase a threshold voltage level of a memory cell selected for programming that has a channel voltage level configured to enable that memory cell for programming, either partially enabled or fully enabled. At least one of the first subset of memory cells, the second subset of memory cells, and the third subset of memory cells might include memory cells of two or more data states of a plurality of possible data states for the programming operation.

As noted, the union of the first subset of memory cells, the second subset of memory cells, and the third subset of memory cells might contain fewer than all memory cells of the plurality of memory cells selected for the programming operation. For such embodiments, additional subsets of memory cells of the plurality of memory cells might be considered. As such, optionally, at 1005, respective channel voltage levels of a fourth subset of memory cells of the plurality of memory cells might be increased to a fourth voltage level higher than the third voltage level prior to applying the programming voltage level to the selected access line. Each memory cell of the fourth subset of memory cells might be connected to the selected access line. And at 1007, the respective channels of the fourth subset of memory cells might be electrically floated while applying the programming voltage level to the selected access line. Additional subsets of memory cells might similarly be considered, with each one having its respective channel voltage levels increased to a higher voltage level, and having its channels electrically floated during application of the programming voltage level to the selected access line.

The first subset of memory cells might include memory cells each having a respective desired data state of the programming operation higher than a highest respective desired data state of any memory cell of the second subset of memory cells. The second subset of memory cells might include memory cells each having a respective desired data state of the programming operation higher than a highest respective desired data state of any memory cell of the third subset of memory cells. In general, the first subset of memory cells might include memory cells each having a respective desired data state of the programming operation lower than or equal to a highest data state of the plurality of possible data states. The second subset of memory cells might include memory cells each having a respective desired data state of the programming operation higher than a lowest data state of the plurality of possible data states and lower than the highest data state. The third subset of memory cells might include memory cells each having a respective desired data state of the programming operation equal to or higher than the lowest data state.

For embodiments addressing more than three subsets of memory cells, the third subset of memory cells might include memory cells each having a respective desired data state of the programming operation higher than a highest respective desired data state of any memory cell of the fourth subset of memory cells. To extend this further, one subset of memory cells might include memory cells each having a respective desired data state of the programming operation higher than a highest respective desired data state of any memory cell of a different subset of memory cells corresponding to a higher channel voltage level.

The programming voltage level might be an initial programming voltage level of a plurality of programming voltage levels of the programming operation. For example, consider the programming operation of FIG. 5, but where the equilibrium pulse 548 incorporates the boosted channel programming techniques as described with reference to the equilibrium pulse 748 of FIG. 7. The initial programming voltage level might be higher than one or more subsequent programming voltage levels of the plurality of programming voltage levels. For example, the voltage level of the equilibrium pulse 548 in this example might be higher than one or more of the voltage levels of the subsequent programming pulses 444. Note that for embodiments utilizing more than one equilibrium pulse 748, a next subsequent programming voltage level might be higher than the initial programming voltage level, whereas for embodiments utilizing only one equilibrium pulse 748, the next subsequent programming voltage level (e.g., the programming voltage level of the programming pulse 444₀) might be lower than the initial programming voltage level.

The controller might be further configured to cause the memory to apply the one or more subsequent programming voltage levels of the plurality of programming voltage levels to the selected access line during further programming of the plurality of memory cells to their respective desired data states. The controller might be further configured to cause the memory to apply the one or more subsequent programming voltage levels of the plurality of programming voltage levels to the selected access line utilizing an incremental step pulse programming technique.

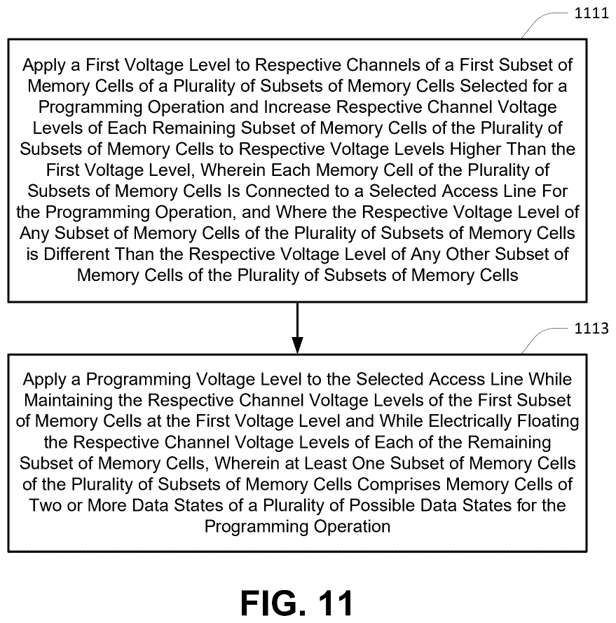

FIG. 11 is a flowchart of a method of operating a memory in accordance with another embodiment. The method might represent actions associated with a programming operation performed by the memory. The method might be in the form of computer-readable instructions, e.g., stored to the instruction registers 128. Such computer-readable instructions might be executed by a controller, e.g., the control logic 116, to cause the relevant components of the memory to perform the method.

At 1111, a first voltage level might be applied to respective channels of a first subset of memory cells of a plurality of subsets of memory cells selected for a programming operation, and respective channel voltage levels of each remaining subset of memory cells of the plurality of subsets of memory cells might be increased to respective voltage levels higher than the first voltage level. Each memory cell of the plurality of subsets of memory cells might be connected to a selected access line for the programming operation. The respective voltage level of any subset of memory cells of the plurality of subsets of memory cells might be different than the respective voltage level of any other subset of memory cells of the plurality of subsets of memory cells. For example, a second subset of memory cells of a plurality of subsets of memory cells might have a second voltage level higher than the first voltage level, a third subset of memory cells of a plurality of subsets of memory cells might have a third voltage level higher than the second voltage level, a fourth subset of memory cells of a plurality of subsets of memory cells might have a fourth voltage level higher than the third voltage level, and so on.

At 1113, a programming voltage level might be applied to the selected access line while maintaining the respective channel voltage levels of the first subset of memory cells at the first voltage level and while electrically floating the respective channel voltage levels of each of the remaining subset of memory cells. At least one subset of memory cells of the plurality of subsets of memory cells comprises memory cells of two or more data states of a plurality of possible data states for the programming operation.

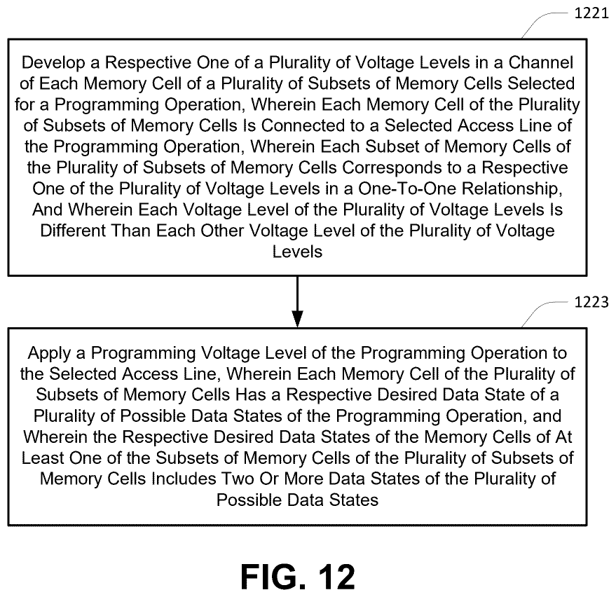

FIG. 12 is a flowchart of a method of operating a memory in accordance with another embodiment. The method might represent actions associated with a programming operation performed by the memory. The method might be in the form of computer-readable instructions, e.g., stored to the instruction registers 128. Such computer-readable instructions might be executed by a controller, e.g., the control logic 116, to cause the relevant components of the memory to perform the method.

At 1221, a respective voltage level of a plurality of voltage levels might be developed in a channel of each memory cell of a plurality of subsets of memory cells selected for a programming operation. Each memory cell of the plurality of subsets of memory cells might be connected to a selected access line of the programming operation. Each subset of memory cells of the plurality of subsets of memory cells might correspond to a respective voltage level of the plurality of voltage levels in a one-to-one relationship. That is, the respective voltage level corresponding to any subset of memory cells of the plurality of subsets of memory cells might be developed in the channel of each memory cell that is a member of that subset. Each voltage level of the plurality of voltage levels further might be different than each other voltage level of the plurality of voltage levels.

At 1223, a programming voltage level of the programming operation might be applied to the selected access line. Each memory cell of the plurality of subsets of memory cells might have a respective desired data state of a plurality of possible data states of the programming operation. The respective desired data states of the memory cells of at least one of the subsets of memory cells of the plurality of subsets of memory cells might include two or more data states of the plurality of possible data states.

A number of subsets of memory cells of the plurality of subsets of memory cells might be greater than or equal to three, and further might be less than a number of data states of the plurality of possible data states. The respective desired data states of the memory cells of a union of each subset of memory cells of the plurality of subsets of memory cells might include each data state of the plurality of possible data states. Furthermore, the respective desired data states of the memory cells of any subset of memory cells of the plurality of subsets of memory cells might be mutually exclusive from the respective desired data states of the memory cells of any other subset of memory cells of the plurality of subsets of memory cells.

Each respective desired data state of the memory cells of a one subset of memory cells of the plurality of subsets of memory cells might be a higher data state than each respective data state of the memory cells of a different subset of memory cells of the plurality of subsets of memory cells if the respective voltage level corresponding to the one subset of memory cells is lower than the respective voltage level corresponding to the different subset of memory cells. Furthermore, a distribution of threshold voltages of the one subset of memory cells might overlap with a distribution of threshold voltages of the different subset of memory cells.

Applying the programming voltage level might result in shifting threshold voltages of a first subset of memory cells of the plurality of subsets of memory cells from a first range of threshold voltages to a second range of threshold voltages higher than the first range of threshold voltages, shifting threshold voltages of a second subset of memory cells of the plurality of subsets of memory cells from the first range of threshold voltages to a third range of threshold voltages lower than the second range of threshold voltages and higher than the first range of threshold voltages, shifting threshold voltages of a third subset of memory cells of the plurality of subsets of memory cells from the first range of threshold voltages to a fourth range of threshold voltages lower than the third range of threshold voltages and higher than the first range of threshold voltages, and inhibiting threshold voltages of a fourth subset of memory cells of the plurality of subsets of memory cells from shifting from the first range of threshold voltages. The second range of threshold voltages might be lower than or equal to a range of threshold voltages corresponding to a lowest data state of the respective desired data states of the memory cells of the first subset of memory cells, the third range of threshold voltages might be lower than or equal to a range of threshold voltages corresponding to a lowest data state of the respective desired data states of the memory cells of the second subset of memory cells, the fourth range of threshold voltages might be lower than or equal to a range of threshold voltages corresponding to a lowest data state of the respective desired data states of the memory cells of the third subset of memory cells, and the first range of threshold voltages might be equal to a range of threshold voltages corresponding to a lowest data state of the plurality of possible data states.

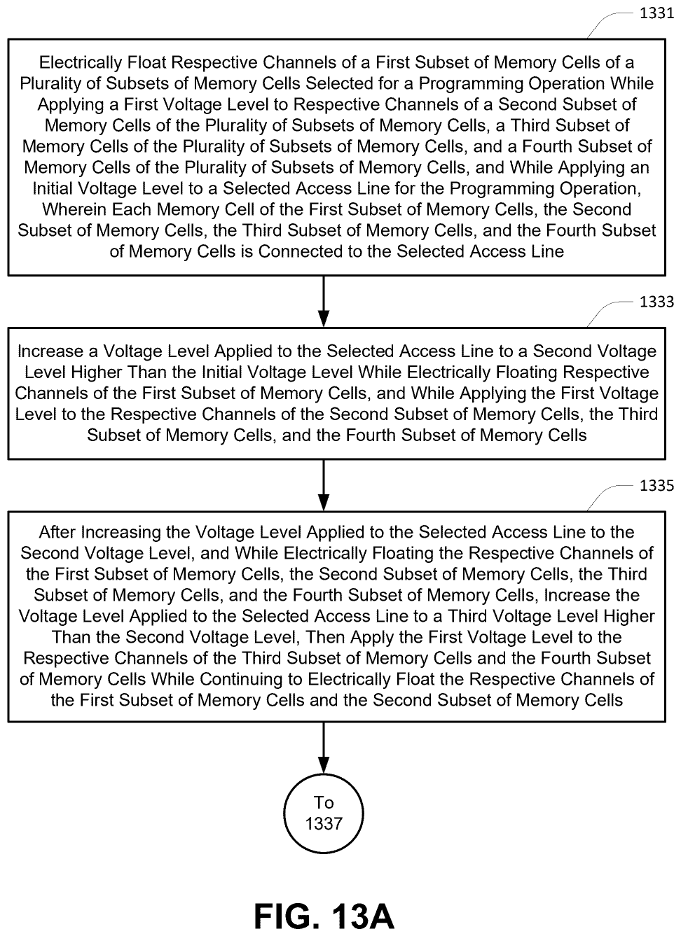

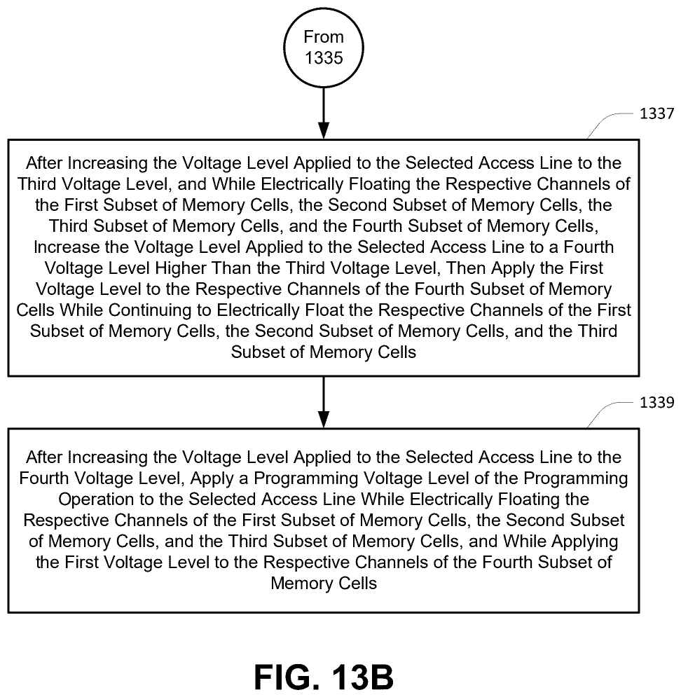

FIGS. 13A-13B are a flowchart of a method of operating a memory in accordance with another embodiment. The method might represent actions associated with a programming operation performed by the memory. The method might be in the form of computer-readable instructions, e.g., stored to the instruction registers 128. Such computer-readable instructions might be executed by a controller, e.g., the control logic 116, to cause the relevant components of the memory to perform the method.

At 1331, respective channels of a first subset of memory cells of a plurality of subsets of memory cells selected for the programming operation might be electrically floated while applying a first voltage level to respective channels of a second subset of memory cells of the plurality of subsets of memory cells, a third subset of memory cells of the plurality of subsets of memory cells, and a fourth subset of memory cells of the plurality of subsets of memory cells, and while applying an initial voltage level to a selected access line of the plurality of access lines selected for the programming operation. Each memory cell of the first subset of memory cells, the second subset of memory cells, the third subset of memory cells, and the fourth subset of memory cells might be connected to the selected access line;

At 1333, a voltage level applied to the selected access line might be increased to a second voltage level higher than the initial voltage level while electrically floating the respective channels of the first subset of memory, and while applying the first voltage level to the respective channels of the second subset of memory cells, the third subset of memory cells, and the fourth subset of memory cells.

At 1335, after increasing the voltage level applied to the selected access line to the second voltage level, and while electrically floating the respective channels of the first subset of memory cells, the second subset of memory cells, the third subset of memory cells, and the fourth subset of memory cells, the voltage level applied to the selected access line might be increased to a third voltage level higher than the second voltage level. The first voltage level might then be applied to the respective channels of the third subset of memory cells and the fourth subset of memory cells while continuing to electrically float the respective channels of the first subset of memory cells and the second subset of memory cells.

At 1337, after increasing the voltage level applied to the selected access line to the third voltage level, and while electrically floating the respective channels of the first subset of memory cells, the second subset of memory cells, the third subset of memory cells, and the fourth subset of memory cells, the voltage level applied to the selected access line might be increased to a fourth voltage level higher than the third voltage level. The first voltage level might then be applied to the respective channels of the fourth subset of memory cells while continuing to electrically float the respective channels of the first subset of memory cells, the second subset of memory cells, and the third subset of memory cells. For embodiments having four subsets of memory cells, the fourth voltage level might be the pass voltage level Vpass.

At 1339, after increasing the voltage level applied to the selected access line to the fourth voltage level, a programming voltage level of the programming operation might be applied to the selected access line while electrically floating the respective channels of the first subset of memory cells, the second subset of memory cells, and the third subset of memory cells, and while applying the first voltage level to the respective channels of the fourth subset of memory cells.

Each memory cell of the first subset of memory cells might have a respective desired data state of the programming operation selected from a group consisting of a first range of data states of a plurality of possible data states of the programming operation from a lowest data state of the plurality of possible data states to a second data state higher than or equal to the lowest data state. As one example, the first subset of memory cells of FIGS. 13A-13B might include L0 memory cells of a TLC memory, e.g., with the second data state being equal to the lowest (e.g., erased or L0) data state.

Each memory cell of the second subset of memory cells might have a respective desired data state of the programming operation selected from a group consisting of a second range of data states of the plurality of possible data states from a third data state of the plurality of possible data states higher than the second data state to a fourth data state of the plurality of possible data states higher than or equal to the third data state. As one example, the second subset of memory cells of FIGS. 13A-13B might include L1-L2 memory cells of the TLC memory, e.g., with the third data state being the L1 data state and the fourth data state being the L2 data state.

Each memory cell of the third subset of memory cells might have a respective desired data state of the programming operation selected from a group consisting of a third range of data states of the plurality of possible data states from a fifth data state of the plurality of possible data states higher than the fourth data state to a sixth data state of the plurality of possible data states higher than or equal to the fifth data state. As one example, the third subset of memory cells might include L3-L4 memory cells of the TLC memory, e.g., with the fifth data state being the L3 data state and the sixth data state being the L4 data state.

Each memory cell of the fourth subset of memory cells might have a respective desired data state of the programming operation selected from a group consisting of a fourth range of data states of the plurality of possible data states from a seventh data state of the plurality of possible data states higher than the sixth data state to an eighth data state of the plurality of possible data states higher than or equal to the seventh data state, which might include the highest data state of the plurality of possible data states. As one example, the fourth subset of memory cells might include L5-L7 memory cells of the TLC memory, e.g., with the seventh data state being the L5 data state and the eighth data state being the highest (e.g., L7) data state. At least one of the first range of data states, the second range of data states, the third range of data states, and the fourth range of data states might include two or more data states of the plurality of possible data states.

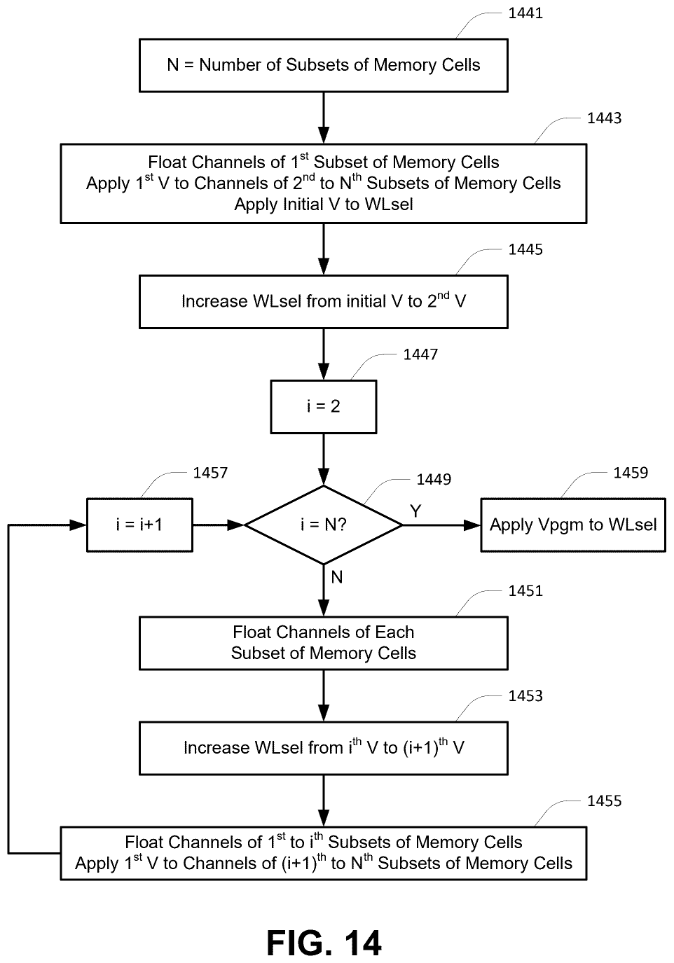

FIG. 14 is a flowchart of a method of operating a memory in accordance with another embodiment. The method might represent actions associated with a programming operation performed by the memory. The method might be in the form of computer-readable instructions, e.g., stored to the instruction registers 128. Such computer-readable instructions might be executed by a controller, e.g., the control logic 116, to cause the relevant components of the memory to perform the method.

At 1441, an integer value N might be equal to a number of subsets of memory cells of a plurality of subsets of memory cells selected for a programming operation, e.g., N subsets of memory cells selected or the programming operation. The value of N might be greater than or equal to three, and less than a number of possible data states for the programming operation.

At 1443, respective channels of a first subset of memory cells of the N subsets of memory cells selected for the programming operation might be electrically floated, a first voltage level might be applied to respective channels of each subset of memory cells of the N subsets of memory cells from a second subset of memory cells to an N^{th} subset of memory cells, and an initial voltage level might be applied to a selected access line (e.g., WLsel) of the programming operation.

At 1445, a voltage level applied to the selected access line might be increased from the initial voltage level to the second voltage level. This might occur while electrically floating the respective channels of the first subset of memory cells, applying the first voltage level to the respective channels of each remaining subset of memory cells of the N subsets of memory cells, and applying the first voltage level to the selected access line. As a result, channel voltage levels of the respective channels of the first subset of memory cells might be increased through capacitive coupling.

At 1447, an integer value i might be equal to 2. The process of 1449-1455 might be repeated for each value of i from 2 to N−1.

At 1449, it might be determined whether i is equal to N. Note that on the first determination, i cannot be equal to N because a minimum value of N has been set to a value of 3 and i has been set to a value of 2 prior to the first determination. In response to i not being equal to N (e.g., being less than N) at 1449, the process might proceed to 1451.

At 1451, the respective channels of each subset of memory cells of the N subsets of memory cells might be electrically floated. At 1453, the voltage level applied to the selected access line might be increased from the i^{th} voltage level to an (i+1)^{th} voltage level. This might occur while electrically floating the respective channels of each subset of memory cells of the N subsets of memory cells. As a result, channel voltage levels of the respective channels of each subset of memory cells of the N subsets of memory cells might be increased through capacitive coupling.

At 1455, the respective channels of each subset of memory cells of the N subsets of memory cells from the first subset of memory cells to an i^{th} subset of memory cells might be (e.g., might continue to be) electrically floated, and the first voltage level might be applied to the respective channels of each subset of memory cells of the N subsets of memory cells from an (i+1)^{th} subset of memory cells to the N^{th} subset of memory cells. As a result, channel voltage levels of the respective channels of each subset of memory cells of the N subsets of memory cells from the first subset of memory cells to the i^{th} subset of memory cells might be increased through capacitive coupling, and channel voltage levels of the respective channels of each subset of memory cells of the N subsets of memory cells from the (i+1)^{th} subset of memory cells to the N^{th} subset of memory cells might be discharged to the first voltage level. At 1457, the value of i might be incremented by 1 (e.g., a step increase of 1) and the process might return to 1449 to repeat the process of 1449-1455 for each remaining value of i that is less than N.

In response to i being equal to N at 1449, the process might proceed to 1459. At 1459, a programming voltage level of the programming operation might be applied to the selected access line. This might occur while electrically floating the respective channels of each subset of memory cells of the N subsets of memory cells from the first subset of memory cells to an (N−1)^{th} subset of memory cells, and applying the first voltage level to the respective channels of the N^{th} subset of memory cells.

For embodiments where N is greater than or equal to four, each memory cell of the first subset of memory cells of the N subsets of memory cells might have a respective desired data state of the programming operation selected from a group consisting of a first range of data states of the plurality of possible data states of the programming operation from a lowest data state of the plurality of possible data states to a second data state higher than or equal to the lowest data state; each memory cell of the second subset of memory cells of the N subsets of memory cells might have a respective desired data state of the programming operation selected from a group consisting of a second range of data states of the plurality of possible data states from a third data state of the plurality of possible data states higher than the second data state to a fourth data state of the plurality of possible data states higher than or equal to the third data state; each memory cell of the third subset of memory cells of the N subsets of memory cells might have a respective desired data state of the programming operation selected from a group consisting of a third range of data states of the plurality of possible data states from a fifth data state of the plurality of possible data states higher than the fourth data state to a sixth data state of the plurality of possible data states higher than or equal to the fifth data state; and each memory cell of the fourth subset of memory cells of the N subsets of memory cells might have a respective desired data state of the programming operation selected from a group consisting of a fourth range of data states of the plurality of possible data states from a seventh data state of the plurality of possible data states higher than the sixth data state to an eighth data state of the plurality of possible data states higher than the seventh data state and lower than or equal to a highest data state of the plurality of possible data states. At least one of the first range of data states, the second range of data states, the third range of data states, and the fourth range of data states might include two or more data states of the plurality of possible data states. The first range of data states might consist of the lowest data state of the plurality of possible data states, and the fourth range of data states comprises the highest data state of the plurality of possible data states. The second range of data states, the third range of data states, and the fourth range of data states might each include two or more data states of the plurality of possible data states.

For some embodiments, the process of FIG. 14 might be repeated for a given programming operation, e.g., embodiments utilizing more than one equilibrium pulse 748. For each subsequent instance of the process of FIG. 14 within a programming operation, the programming voltage level might be increased.

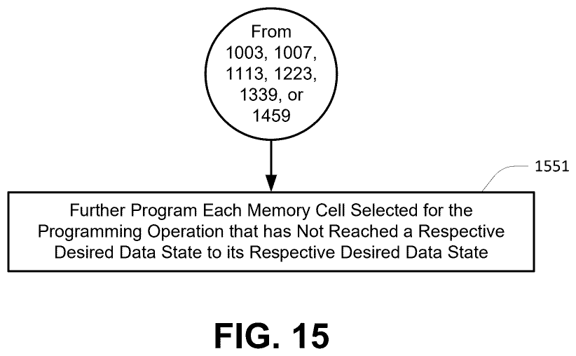

FIG. 15 is a flowchart of a method of operating a memory in accordance with another embodiment. The method might represent actions associated with a programming operation performed by the memory. The method might be in the form of computer-readable instructions, e.g., stored to the instruction registers 128. Such computer-readable instructions might be executed by a controller, e.g., the control logic 116, to cause the relevant components of the memory to perform the method.

The actions of FIG. 15 might be performed subsequent to any one of the actions 1003 of FIG. 10, 1007 of FIG. 10, 1113 of FIG. 11, 1223 of FIG. 12, 1339 of FIGS. 13A-13B, or 1459 of FIG. 14. At 1551, each memory cell selected for the programming operation that has not reached a respective desired data state of the programming operation might be further programmed to its respective desired data state. Further programming might occur as discussed with reference to FIG. 5, beginning with the application of the programming pulse 4400 to the selected access line. More broadly, further programming might utilize any known programming technique configured to move a threshold voltage of a memory cell to a range of threshold voltages corresponding to its desired data state of the programming operation.

### CONCLUSION

Although specific embodiments have been illustrated and described herein, it will be appreciated by those of ordinary skill in the art that any arrangement that is calculated to achieve the same purpose might be substituted for the specific embodiments shown. Many adaptations of the embodiments will be apparent to those of ordinary skill in the art. Accordingly, this application is intended to cover any adaptations or variations of the embodiments.

What is claimed is:

1. A memory, comprising:
an array of memory cells comprising a plurality of strings of series-connected memory cells;
a plurality of access lines, wherein each access line of the plurality of access lines is connected to a control gate of a respective memory cell of each string of series-connected memory cells of the plurality of strings of series-connected memory cells; and
a controller for access of the array of memory cells, wherein the controller, during a programming operation, is configured to cause the memory to:
develop a respective voltage level of a plurality of voltage levels in a channel of each memory cell of a plurality of subsets of memory cells selected for a programming operation, wherein each memory cell of the plurality of subsets of memory cells is connected to a selected access line of the programming operation, wherein each subset of memory cells of the plurality of subsets of memory cells corresponds to a respective voltage level of the plurality of voltage levels in a one-to-one relationship, and wherein each voltage level of the plurality of voltage levels is different than each other voltage level of the plurality of voltage levels; and
apply a programming voltage level of the programming operation to the selected access line;
wherein each memory cell of the plurality of subsets of memory cells has a respective desired data state of a plurality of possible data states of the programming operation; and
wherein the respective desired data states of the memory cells of at least one of the subsets of memory cells of the plurality of subsets of memory cells include two or more data states of the plurality of possible data states.

2. The memory of claim 1, wherein a number of subsets of memory cells of the plurality of subsets of memory cells is greater than or equal to three, and less than a number of data states of the plurality of possible data states.

3. The memory of claim 2, wherein the respective desired data states of the memory cells of a union of each subset of memory cells of the plurality of subsets of memory cells includes each data state of the plurality of possible data states.

4. The memory of claim 2, wherein each respective desired data state of the memory cells of a first subset of memory cells of the plurality of subsets of memory cells is a higher data state than each respective data state of the memory cells of a second subset of memory cells of the plurality of subsets of memory cells, and wherein the respective voltage level corresponding to the first subset of memory cells is lower than the respective voltage level corresponding to the second subset of memory cells.

5. The memory of claim 4, wherein a distribution of threshold voltages of the first subset of memory cells overlaps with a distribution of threshold voltages of the second subset of memory cells.

6. The memory of claim 1, wherein the controller is further configured to cause the memory to:
in response to applying the programming voltage level:
shift threshold voltages of a first subset of memory cells of the plurality of subsets of memory cells from a first range of threshold voltages to a second range of threshold voltages higher than the first range of threshold voltages;
shift threshold voltages of a second subset of memory cells of the plurality of subsets of memory cells from the first range of threshold voltages to a third range of threshold voltages lower than the second range of threshold voltages and higher than the first range of threshold voltages;
shift threshold voltages of a third subset of memory cells of the plurality of subsets of memory cells from the first range of threshold voltages to a fourth range of threshold voltages lower than the third range of threshold voltages and higher than the first range of threshold voltages; and
inhibit threshold voltages of a fourth subset of memory cells of the plurality of subsets of memory cells from shifting from the first range of threshold voltages.

7. The memory of claim 6, wherein the second range of threshold voltages is lower than or equal to a range of threshold voltages corresponding to a lowest data state of the respective desired data states of the memory cells of the first subset of memory cells, wherein the third range of threshold voltages is lower than or equal to a range of threshold voltages corresponding to a lowest data state of the respective desired data states of the memory cells of the second subset of memory cells, wherein the fourth range of threshold voltages is lower than or equal to a range of threshold voltages corresponding to a lowest data state of the respective desired data states of the memory cells of the third subset of memory cells, and wherein the first range of threshold voltages is equal to a range of threshold voltages corresponding to a lowest data state of the plurality of possible data states.

8. The memory of claim 1, wherein the controller is further configured to cause the memory to:
in response to applying the programming voltage level:
shift threshold voltages of a fifth subset of memory cells of the plurality of subsets of memory cells from the first range of threshold voltages to a fifth range of threshold voltages higher than the second range of threshold voltages and higher than the first range of threshold voltages;
wherein the fifth range of threshold voltages is lower than or equal to a range of threshold voltages corresponding to a lowest data state of the respective desired data states of the memory cells of the fifth subset of memory cells.

9. A memory, comprising:
an array of memory cells comprising a plurality of strings of series-connected memory cells;
a plurality of access lines, wherein each access line of the plurality of access lines is connected to a control gate of a respective memory cell of each string of series-connected memory cells of the plurality of strings of series-connected memory cells; and
a controller for access of the array of memory cells, wherein the controller, during a programming operation, is configured to cause the memory to:
apply a first voltage level to respective channels of a first subset of memory cells of a plurality of memory cells selected for the programming operation, increase respective channel voltage levels of a second subset of memory cells of the plurality of memory cells to a second voltage level higher than the first voltage level, and increase respective channel voltage levels of a third subset of memory cells of the plurality of memory cells to a third voltage level higher than the second voltage level, wherein each memory cell of the first subset of memory cells, the second subset of memory cells, and the third subset of memory cells is connected to a selected access line of the plurality of access lines for the programming operation; and
apply a programming voltage level to the selected access line while maintaining the respective channel voltage levels of the first subset of memory cells at the first voltage level and while electrically floating respective channels of the second subset of memory cells and the third subset of memory cells;
wherein at least one of the first subset of memory cells, the second subset of memory cells, and the third subset of memory cells comprises memory cells of two or more desired data states of a plurality of possible data states for the programming operation within its respective desired data states.

10. The memory of claim 9, wherein the first subset of memory cells comprises memory cells each having a respective desired data state of the programming operation lower than or equal to a highest data state of the plurality of possible data states, wherein the second subset of memory cells comprises memory cells each having a respective desired data state of the programming operation higher than a lowest data state of the plurality of possible data states and lower than the highest data state, and wherein the third subset of memory cells comprises memory cells each having a respective desired data state of the programming operation equal to or higher than the lowest data state.

11. The memory of claim 9, wherein the programming voltage level is an initial programming voltage level of a plurality of programming voltage levels of the programming operation, and wherein the initial programming voltage level is higher than one or more subsequent programming voltage levels of the plurality of programming voltage levels.

12. The memory of claim 11, wherein the controller is further configured to cause the memory to apply the one or more subsequent programming voltage levels of the plurality of programming voltage levels to the selected access line during further programming of the plurality of memory cells to their respective desired data states.

13. The memory of claim 12, wherein the controller is further configured to cause the memory to apply the one or more subsequent programming voltage levels of the plurality of programming voltage levels to the selected access line utilizing an incremental step pulse programming technique.

14. The memory of claim 9, wherein the controller being configured to cause the memory to increase the respective channel voltage levels of the second subset of memory cells to the second voltage level and to increase the respective channel voltage levels of the third subset of memory cells to the third voltage level comprises the controller being configured to cause the memory to:
prior to applying the programming voltage level, electrically float the respective channel voltage levels of the second subset of memory cells and the third subset of memory cells, then increase a voltage level applied to the selected access line; and
after increasing the voltage level applied to the selected access line, discharge the respective channel voltage levels of the second subset of memory cells to the first voltage level while continuing to electrically float the respective channel voltage levels of the third subset of memory cells.

15. A memory, comprising:
an array of memory cells comprising a plurality of strings of series-connected memory cells;
a plurality of access lines, wherein each access line of the plurality of access lines is connected to a respective memory cell of each string of series-connected memory cells of the plurality of strings of series-connected memory cells; and
a controller for access of the array of memory cells, wherein the controller, during a programming operation, is configured to cause the memory to:
electrically float respective channels of a first subset of memory cells of N subsets of memory cells selected for the programming operation, apply a first voltage level to respective channels of each remaining subset of memory cells of the N subsets of memory cells, and apply the first voltage level to a selected access line for the programming operation, wherein N is greater than or equal to three and less than a number of data states of a plurality of possible data states of the programming operation;
increase a voltage level applied to the selected access line from the first voltage level to the second voltage level;
for each value of i from 2 to N−1 step 1:
electrically float the respective channels of each subset of memory cells of the N subsets of memory cells from the first subset of memory cells to an N^{th} subset of memory cells;
increase the voltage level applied to the selected access line from an i^{th} voltage level to an (i+1)^{th} voltage level; and
continue to electrically float the respective channels of each subset of memory cells of the N subsets of memory cells from the first subset of memory cells to an i^{th} subset of memory cells, and apply the first voltage level to the respective channels of each subset of memory cells of the N subsets of memory cells from an (i+1)^{th} subset of memory cells to the N^{th} subset of memory; and
apply a programming voltage level of the programming operation to the selected access line while electrically floating the respective channels of each subset of memory cells of the N subsets of memory cells from the first subset of memory cells to an (N−1)^{th} subset of memory cells, and while applying the first voltage level to the respective channels of the N^{th} subset of memory cells.

16. The memory of claim 15, wherein N is greater than or equal to four, the memory further comprising:
wherein each memory cell of the first subset of memory cells of the N subsets of memory cells has a respective desired data state of the programming operation selected from a group consisting of a first range of data states of the plurality of possible data states of the programming operation from a lowest data state of the plurality of possible data states to a second data state higher than or equal to the lowest data state;
wherein each memory cell of the second subset of memory cells of the N subsets of memory cells has a respective desired data state of the programming operation selected from a group consisting of a second range of data states of the plurality of possible data states from a third data state of the plurality of possible data states higher than the second data state to a fourth data state of the plurality of possible data states higher than or equal to the third data state;
wherein each memory cell of the third subset of memory cells of the N subsets of memory cells has a respective desired data state of the programming operation selected from a group consisting of a third range of data states of the plurality of possible data states from a fifth data state of the plurality of possible data states higher than the fourth data state to a sixth data state of the plurality of possible data states higher than or equal to the fifth data state;
wherein each memory cell of the fourth subset of memory cells of the N subsets of memory cells has a respective desired data state of the programming operation selected from a group consisting of a fourth range of data states of the plurality of possible data states from a seventh data state of the plurality of possible data states higher than the sixth data state to an eighth data state of the plurality of possible data states higher than the seventh data state and lower than or equal to a highest data state of the plurality of possible data states; and
wherein at least one of the first range of data states, the second range of data states, the third range of data states, and the fourth range of data states comprises two or more data states of the plurality of possible data states.

17. The memory of claim 16, wherein N is equal to four, wherein the first range of data states consists of the lowest data state of the plurality of possible data states, and wherein the fourth range of data states comprises the highest data state of the plurality of possible data states.

18. The memory of claim 17, wherein the second range of data states, the third range of data states, and the fourth range of data states each comprise two or more data states of the plurality of possible data states.

19. The memory of claim 15, wherein the controller, after applying the programming voltage level to the selected access line, is further configured to cause the memory to further program each memory cell of the N subsets of memory cells to a respective desired data state of the plurality of possible data states of the programming operation.

20. The memory of claim 15, wherein the programming voltage level is an initial programming voltage level, and wherein the controller is further configured to cause the memory to:
electrically float the respective channels of the first subset of memory cells, apply the first voltage level to the respective channels of each remaining subset of memory cells of the N subsets of memory cells, and apply the first voltage level to the selected access line;
increase the voltage level applied to the selected access line from the first voltage level to the second voltage level;
for each value of i from 2 to N−1 step 1:
electrically float the respective channels of each subset of memory cells of the N subsets of memory cells from the first subset of memory cells to the N^{th} subset of memory cells;
increase the voltage level applied to the selected access line from the i^{th} voltage level to the (i+1)^{th} voltage level; and
continue to electrically float the respective channels of each subset of memory cells of the N subsets of memory cells from the first subset of memory cells to the i^{th} subset of memory cells, and apply the first voltage level to the respective channels of each subset of memory cells of the N subsets of memory cells from the (i+1)^{th} subset of memory cells to the N^{th} subset of memory; and
apply a subsequent programming voltage level of the programming operation, higher than the initial programming voltage level, to the selected access line while electrically floating the respective channels of each subset of memory cells of the N subsets of memory cells from the first subset of memory cells to the (N−1)^{th} subset of memory cells, and while applying the first voltage level to the respective channels of the N^{th} subset of memory cells.
